(19) United States
(12) Patent Application Publication
(10) Pub. No.: US 2026/0039974 A1
(43) Pub. Date: Feb. 5, 2026

(54) PHOTOELECTRIC CONVERSION APPARATUS, PHOTOELECTRIC CONVERSION SYSTEM, DEVICE, AND SIGNAL PROCESSING METHOD FOR PHOTOELECTRIC CONVERSION APPARATUS

(71) Applicant: CANON KABUSHIKI KAISHA, Tokyo (JP)

(72) Inventors: HIDETOSHI HAYASHI, Kanagawa (JP); KAZUNORI MATSUYAMA, Kanagawa (JP); SHINYA IGARASHI, Kanagawa (JP); HIROTAKA SHUKURI, Tokyo (JP); NORIYUKI SHIKINA, Tokyo (JP)

(21) Appl. No.: 19/277,173

(22) Filed: Jul. 22, 2025

(30) Foreign Application Priority Data
Aug. 1, 2024 (JP) 2024-125745

(51) Int. Cl. H04N 25/704; H10F 39/00

(52) U.S. Cl. CPC H04N 25/704; H10F 39/8053; H10F 39/8063

(57) ABSTRACT

A conversion apparatus including a plurality of pixels disposed in a matrix, the conversion apparatus including a first pixel and a second pixel disposed in a first row, a first microlens corresponding to the first pixel, and a second microlens corresponding to the second pixel, wherein using a first control line, a set of a signal based on a first charge and a signal based on a fourth charge is output for use in focus detection and image generation.

### BACKGROUND

### Field of the Technology

The aspect of the embodiments relates to a photoelectric conversion apparatus, a photoelectric conversion system, a device, and a signal processing method for a photoelectric conversion apparatus.

### Description of the Related Art

Japanese Patent Application Laid-Open No. 2020-98968 discusses an imaging element that includes pixels including a plurality of photodiodes and outputs a signal for focus detection and a signal for image generation.

While the imaging element discussed in Japanese Patent Application Laid-Open No. 2020-98968 outputs a signal corresponding to a single frame as the signal for the focus detection, the imaging element outputs signals corresponding to a plurality of frames as the signal for the image generation.

This decreases the frame rate when the image generation is performed.

### SUMMARY

According to an aspect of the embodiments, a conversion apparatus including a plurality of pixels disposed in a matrix includes a first pixel and a second pixel disposed in a first row, a first microlens corresponding to the first pixel, and a second microlens corresponding to the second pixel, wherein the first pixel includes a first conversion element configured to convert light passing through the first microlens, thereby generating a first charge, a second conversion element configured to convert light passing through the first microlens, thereby generating a second charge, a first floating diffusion configured to accumulate at least one of the first and second charges, a first transfer transistor configured to transfer the first charge to the first floating diffusion, and a second transfer transistor configured to transfer the second charge to the first floating diffusion, and wherein the second pixel includes a third conversion element configured to convert light passing through the second microlens, thereby generating a third charge, a fourth conversion element configured to convert light passing through the second microlens, thereby generating a fourth charge, a second floating diffusion configured to accumulate at least one of the third and fourth charges, a third transfer transistor configured to transfer the third charge to the second floating diffusion, and a fourth transfer transistor configured to transfer the fourth charge to the second floating diffusion, the conversion apparatus comprising a first control line connected to the first and fourth transfer transistors and a second control line connected to the second and third transfer transistors, wherein the third and fourth conversion elements are disposed in order in a direction from the first conversion element to the second conversion element, and wherein using the first control line, a set of a signal based on the first charge and a signal based on the fourth charge is output for use in focus detection and image generation.

Features of the disclosure will become apparent from the following description of embodiments with reference to the attached drawings. The following description of embodiments is described by way of example.

### BRIEF DESCRIPTION OF THE DRAWINGS

FIG. 1 is a block diagram illustrating a photoelectric conversion apparatus according to a first exemplary embodiment.

FIGS. 2A and 2B are circuit diagrams illustrating the photoelectric conversion apparatus according to the first exemplary embodiment.

FIG. 3 is a plan view illustrating the photoelectric conversion apparatus according to the first exemplary embodiment.

FIG. 4 is a block diagram illustrating the photoelectric conversion apparatus according to the first exemplary embodiment.

FIG. 5 is a driving timing chart illustrating the photoelectric conversion apparatus according to the first exemplary embodiment.

FIG. 6 is a block diagram illustrating the photoelectric conversion apparatus according to the first exemplary embodiment.

FIG. 7 is a block diagram illustrating a photoelectric conversion apparatus according to a second exemplary embodiment.

FIG. 8 is a block diagram illustrating the photoelectric conversion apparatus according to the second exemplary embodiment.

FIGS. 9A, 9B, and 9C are circuit diagrams illustrating the photoelectric conversion apparatus according to the second exemplary embodiment.

FIG. 10 is a block diagram illustrating a photoelectric conversion apparatus according to a third exemplary embodiment.

FIGS. 11A, 11B, and 11C are circuit diagrams illustrating the photoelectric conversion apparatus according to the third exemplary embodiment.

FIG. 12 is a driving timing chart illustrating the photoelectric conversion apparatus according to the third exemplary embodiment.

FIG. 13 is a driving timing chart illustrating the photoelectric conversion apparatus according to the third exemplary embodiment.

FIG. 14 is a driving timing chart illustrating the photoelectric conversion apparatus according to the third exemplary embodiment.

FIG. 15 is a driving timing chart illustrating a photoelectric conversion apparatus according to a fourth exemplary embodiment.

FIGS. 16A, 16B, and 16C are schematic diagrams illustrating a device according to a fifth exemplary embodiment.

### DESCRIPTION OF THE EMBODIMENTS

Exemplary embodiments will be described below with reference to the drawings. The following exemplary embodiments do not limit the disclosure according to the appended claims. Although a plurality of features is described in the exemplary embodiments, not all the plurality of features is essential for the disclosure, and the plurality of features may be optionally combined together. Further, in the attached drawings, the same or similar components are designated by the same reference numbers, and are not redundantly described. In the following exemplary embodiments, a sensor for imaging is mainly described as an example of a photoelectric conversion apparatus. The exemplary embodiments, however, are not limited to a sensor for imaging, and are also applicable to other examples of the photoelectric conversion apparatus. The other examples include an imaging apparatus, a distance measuring apparatus (an apparatus that measures a distance using focus detection or time of flight (ToF)), and a photometric apparatus (an apparatus that measures the amount of incident light).

In the specification, terms indicating particular directions and positions (e.g., “up”, “down”, “right”, and “left” and other terms including these terms) are used where necessary. These terms are used to facilitate the understanding of the exemplary embodiments with reference to the drawings, and the meanings of the terms do not limit the technical scope of the disclosure.

If it is stated “a member A and a member B are electrically connected together” in the specification, this is not limited to a case where the members A and B are directly connected together. In one embodiment, the members A and B only need to be electrically connected together, for example, even if another member C is connected between the members A and B.

In the specification, a “plane” refers to a surface in a direction parallel to a main surface of a substrate. The main surface of the substrate can be a light incident surface of a substrate including a photoelectric conversion element, a surface on which a plurality of analog-to-digital (AD) conversion circuits is repeatedly disposed, or a joint surface between substrates in a laminated photoelectric conversion apparatus. A “planar view” refers to a view from a direction perpendicular to the main surface of the substrate. Further, a “cross section” refers to a surface in a direction perpendicular to a light incident surface of a semiconductor layer.

A “cross-sectional view” refers to a view from a direction parallel to the main surface of the substrate.

A metal member such as a wire or a pad described in the specification may be composed of a metal simple substance of a certain single element, or may be a mixture (an alloy). For example, a wire described as a copper wire may be composed of a copper simple substance, or may mainly include copper and further include another component. For example, a pad connected to an external terminal may be composed of an aluminum simple substance, or may mainly include aluminum and further include another component. The copper wire and the aluminum pad illustrated here are merely examples, and can be changed to various metals. The wire and the pad illustrated here are merely examples of a metal member used in a photoelectric conversion apparatus, and the aspect of the embodiments can also be applied to another metal member.

In the following exemplary embodiments, a form is described in which a plurality of signals is added together. This addition means the mixture of the plurality of signals. Thus, a signal obtained by the addition is not limited to the sum of the plurality of signals. For example, to give a description using two signals, namely a signal A and a signal B, as the plurality of signals, the “addition” in the following exemplary embodiments is not limited to A+B, which is the sum of the signals A and B. For example, a form may be employed in which the “addition” is performed by obtaining a signal of the average of the signals A and B. The “addition” may also be an addition process using a signal obtained by multiplying at least one of the signals A and B by a coefficient. That is, if coefficients α and β are used, a form in which a signal of α×A+β×B is obtained is also included in the range of the addition of the signals A and B.

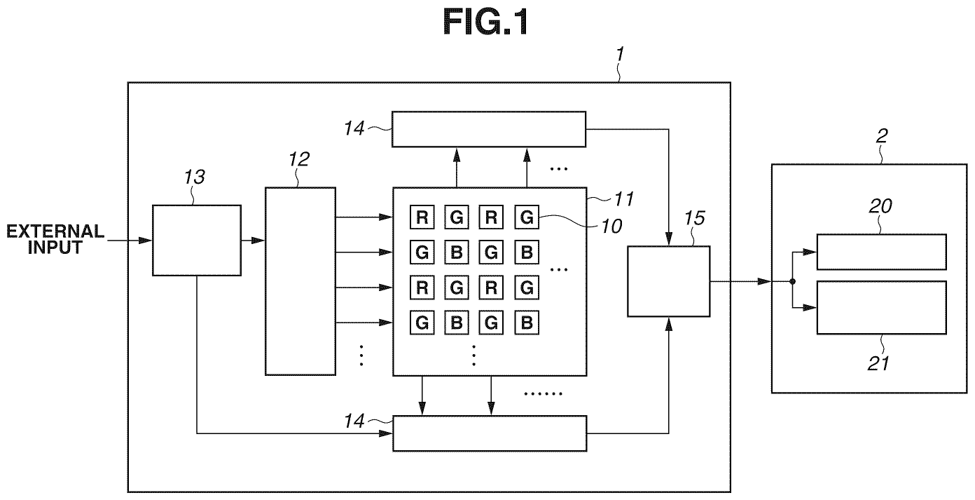

With reference to FIGS. 1 to 6, a photoelectric conversion apparatus 1 (a signal processing method for a photoelectric conversion apparatus) according to a first exemplary embodiment of the disclosure is described.

FIG. 1 is an example of a block diagram of the photoelectric conversion apparatus 1 according to the present exemplary embodiment.

As illustrated in FIG. 1, the photoelectric conversion apparatus 1 includes a pixel array 11, a vertical scanning circuit 12, a timing signal output circuit 13, an AD conversion unit 14, and a signal output circuit 15. A signal correction circuit 2 includes a focus detection circuit 20 and an image generation circuit 21. The signal correction circuit 2 executes signal processing on a signal output from the signal output circuit 15. FIG. 1 illustrates a form in which the signal correction circuit 2 is disposed outside the photoelectric conversion apparatus 1. Typically, a form is employed in which the signal correction circuit 2 is provided on a chip different from a chip on which the photoelectric conversion apparatus 1 is formed. The present exemplary embodiment is not limited to this form, and the signal correction circuit 2 may be disposed inside the photoelectric conversion apparatus 1.

In the pixel array 11, a plurality of pixels 10 is disposed in a matrix over a plurality of rows and a plurality of columns. Each of the plurality of pixels 10 includes a photoelectric conversion element that generates and accumulates a charge according to the amount of received light. The pixel 10 outputs a pixel signal by photoelectric conversion. In the specification, the horizontal direction in the drawings is occasionally referred to as a “row direction”, and the vertical direction in the drawings is occasionally referred to as a “column direction”. The number of rows and the number of columns of the plurality of pixels 10 disposed in the pixel array 11 are not particularly limited. The plurality of pixels 10 may include an effective pixel that outputs a pixel signal according to the amount of incident light, an optical black pixel in which a photoelectric conversion element is shielded from light, and a dummy pixel that does not output a signal to an output line 108.

Color filters in the Bayer arrangement are disposed corresponding to the plurality of pixels 10. For example, among pixels 10 disposed in odd-numbered rows, red color filters are disposed corresponding to pixels 10 disposed in odd-numbered columns, and green color filters are disposed corresponding to pixels 10 disposed in even-numbered columns. Further, for example, among pixels 10 disposed in even-numbered rows, green color filters are disposed corresponding to pixels 10 disposed in the odd-numbered columns, and blue color filters are disposed corresponding to pixels 10 disposed in the even-numbered columns. The red color filters, the green color filters, and the blue color filters are occasionally represented as “R”, “G”, and “B”, respectively.

The vertical scanning circuit 12 sequentially selects a predetermined row among the plurality of rows in which the pixels 10 are disposed, and supplies a driving signal to each row. The timing signal output circuit 13 supplies a vertical address signal, a control timing signal, and a driving signal for each pixel 10 to the vertical scanning circuit 12.

The timing signal output circuit 13 supplies a control timing signal and a horizontal scanning signal to the AD conversion unit 14. The timing signal output circuit 13 may be able to set reference driving for the photoelectric conversion apparatus 1 by an external input, and change the settings of the photoelectric conversion apparatus 1 through communication. A signal output from the timing signal output circuit 13 may be generated by the timing signal output circuit 13, or may be generated by a circuit different from the timing signal output circuit 13.

The AD conversion unit 14 includes AD conversion circuits corresponding to the columns in which the pixels 10 are disposed. The AD conversion unit 14 performs AD conversion on pixel signals that are analog signals input from the pixels 10, and outputs digital signals. A plurality of AD conversion units 14 may be disposed in the vertical direction relative to (above and below) the pixel array 11. For example, pixel signals output from the pixels 10 disposed in the odd-numbered columns are input to the lower AD conversion unit 14, and pixel signals output from the pixels 10 disposed in the even-numbered columns are input to the upper AD conversion unit 14. As the AD conversion method, various AD conversion methods such as slope AD conversion, successive approximation AD conversion, and AZ AD conversion can be used.

Digital signals processed by the AD conversion unit 14 are temporarily held in, for example, a memory included in the AD conversion unit 14. The held digital signals are horizontally scanned, whereby the digital signals are input to the signal output circuit 15. The signal output circuit 15 outputs a signal compliant with a protocol in a system to the signal correction circuit 2 via a bus.

The focus detection circuit 20 can perform focus detection by phase difference detection, using output signals of the photoelectric conversion apparatus 1 based on signals output from the pixels 10. The image generation circuit 21 can perform image generation by adding a plurality of signals using the same signals as the signals used in the focus detection. As described above, the same signals are supplied to the focus detection circuit 20 and the image generation circuit 21, whereby it is possible to perform focus detection while performing image generation in a single frame.

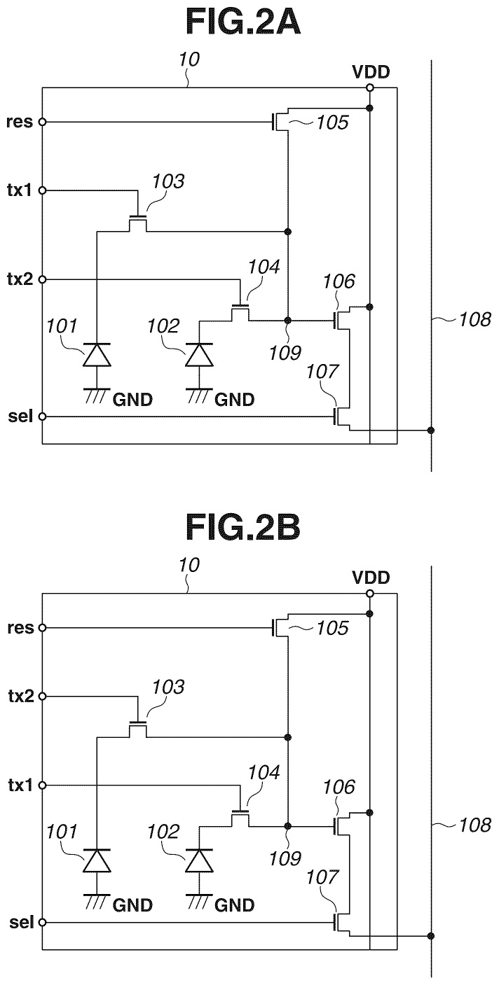

FIGS. 2A and 2B are examples of circuit diagrams of pixels 10 included in the photoelectric conversion apparatus 1 according to the present exemplary embodiment. The aspect of the embodiments can be applied to both front-side illumination and back-side illumination sensors.

As illustrated in FIG. 2A, a pixel 10 includes a first photoelectric conversion element 101, a second photoelectric conversion element 102, a first transfer transistor 103, a second transfer transistor 104, and a floating diffusion 109. Hereinafter, in the specification, the floating diffusion 109 is occasionally referred to as the “FD 109”. The FD 109 is occasionally referred to also as the “floating diffusion area 109”. Further, the pixel 10 includes a reset transistor 105 for resetting the FD 109, an amplification transistor 106 for amplifying a signal, and a selection transistor 107. The first photoelectric conversion element 101 and the second photoelectric conversion element 102 are electrically connected to reference voltage nodes GND, and reference voltages are supplied to the first photoelectric conversion element 101 and the second photoelectric conversion element 102. The reset transistor 105 and the amplification transistor 106 are electrically connected to a power supply voltage node VDD, and a power supply voltage is supplied to the reset transistor 105 and the amplification transistor 106.

The voltage of the power supply voltage node VDD is a voltage of 1 to 5 V. Although the voltage of each reference voltage node GND is 0 V, the aspect of the embodiments is not limited to this form. For example, the voltage of each reference voltage node GND may be a negative voltage, or may be a positive voltage smaller than the voltage of the power supply voltage node VDD. Each of the voltages of the power supply voltage node VDD and the reference voltage nodes GND may be variable.

Each of the first transfer transistor 103, the second transfer transistor 104, the reset transistor 105, the amplification transistor 106, and the selection transistor 107 may be an N-type metal-oxide-semiconductor (MOS) transistor, or may be a P-type MOS transistor. In the present exemplary embodiment, a case is described where an electron in an electron-hole pair generated in each of the first photoelectric conversion element 101 and the second photoelectric conversion element 102 by the incidence of light is used as a signal charge. In a case where an electron is used as a signal charge, each transistor included in the pixel 10 can be configured as an N-type MOS transistor. However, a signal charge is not limited to an electron, and a hole may be used as a signal charge. In a case where a hole is used as a signal charge, each transistor included in the pixel 10 can be configured as a P-type MOS transistor, which is different from the transistor described in the present exemplary embodiment.

For example, each of the first photoelectric conversion element 101 and the second photoelectric conversion element 102 is a photodiode. Each of the first photoelectric conversion element 101 and the second photoelectric conversion element 102 is not limited to a photodiode, and for example, may be a photoelectric conversion film. Each of the first photoelectric conversion element 101 and the second photoelectric conversion element 102 receives light incident on the pixel 10, generates a charge according to the incident light, and accumulates the charge. The reset transistor 105 is driven by a control signal res. The reset transistor 105 is turned on (enters a conducting state), whereby the FD 109 is reset to a voltage based on the power supply voltage. Then, the reset transistor 105 is turned off (enters a non-conducting state), whereby the reset of the FD 109 is cancelled. The first transfer transistor 103 is driven by a control signal tx1. The first transfer transistor 103 is turned on, whereby a charge generated in the first photoelectric conversion element 101 is transferred to the FD 109. The second transfer transistor 104 is driven by a control signal tx2. The second transfer transistor 104 is turned on, whereby a charge generated in the second photoelectric conversion element 102 is transferred to the FD 109. The FD 109 functions as a charge voltage conversion unit that temporarily holds a charge input from at least one of the first photoelectric conversion element 101 and the second photoelectric conversion element 102 and converts the held charge into a voltage signal. The amplification transistor 106 amplifies a pixel signal (a voltage signal) converted by the FD 109. The selection transistor 107 is driven by a control signal sel, connects the amplification transistor 106 to an output line 108, and outputs a pixel signal amplified by the amplification transistor 106 to the output line 108. Examples of the pixel signal may include a signal (a noise signal) at the reset level of the FD 109 and signals (photoelectric conversion signals) output from the first photoelectric conversion element 101 and the second photoelectric conversion element 102. A noise signal is a signal mainly including a noise component included in the pixel 10.

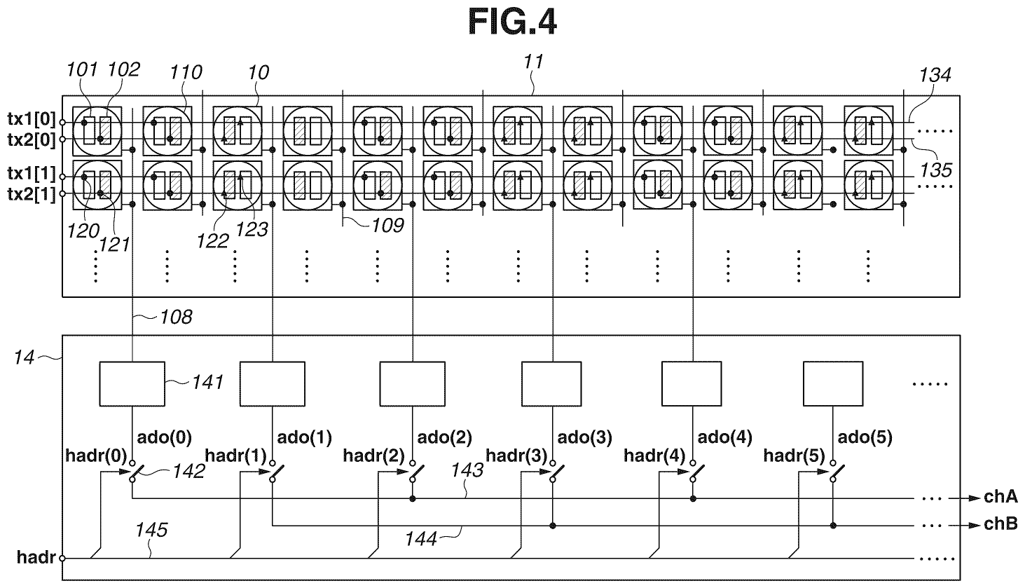

A pixel 10 illustrated in FIG. 2B is different from the pixel 10 illustrated in FIG. 2A in the correspondence relationships between the control signals and the transfer transistors (the photoelectric conversion elements). Specifically, in the pixel 10 illustrated in FIG. 2B, the first transfer transistor 103 is driven by the control signal tx2, and the second transfer transistor 104 is driven by the control signal tx1. The pixel 10 illustrated in FIG. 2A is occasionally referred to as “a pixel 10 of a type A”, and the pixel 10 illustrated in FIG. 2B is occasionally referred to as “a pixel 10 of a type B”. The pixel array 11 includes both pixels 10 of the type A and pixels 10 of the type B. The detailed configuration will be described below with reference to FIG. 4.

In the present exemplary embodiment, the common amplification transistor 106 is disposed corresponding to two photoelectric conversion elements, namely the first photoelectric conversion element 101 and the second photoelectric conversion element 102. The first transfer transistor 103 and the second transfer transistor 104 are driven at the same timing, whereby pixel signals are output from the first photoelectric conversion element 101 and the second photoelectric conversion element 102. Then, the FD 109 adds the pixel signals output from the first photoelectric conversion element 101 and the second photoelectric conversion element 102, whereby a signal for image generation can be output. On the other hand, the first transfer transistor 103 and the second transfer transistor 104 are driven at different timings, whereby a phase difference signal for focus detection can be output.

The configuration of each of the pixels 10 illustrated in FIGS. 2A and 2B is merely an example. The pixel 10 may further include a transistor having a predetermined function. For example, a transistor that changes the capacitance value of the FD 109, or a transistor that discharges a charge from at least one of the first photoelectric conversion element 101 and the second photoelectric conversion element 102 may be further provided. A configuration may be employed in which the pixel 10 does not include the selection transistor 107, and the selected and non-selected states of the pixel 10 are changed based on a voltage input from the reset transistor 105 to the FD 109. A configuration may be employed in which in a case where a plurality of output lines 108 is disposed in a single pixel column, a single pixel 10 includes a plurality of selection transistors 107 connected to output lines 108 different from each other. Although in each of the pixels 10 illustrated in FIGS. 2A and 2B, the first photoelectric conversion element 101 and the second photoelectric conversion element 102 share the FD 109, an FD 109 may be provided corresponding to each of the first photoelectric conversion element 101 and the second photoelectric conversion element 102.

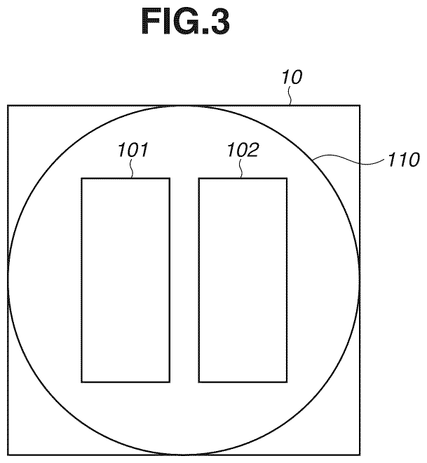

FIG. 3 is an example of a plan view of a pixel 10 included in the photoelectric conversion apparatus 1 according to the present exemplary embodiment.

As illustrated in FIG. 3, a microlens 110 is disposed corresponding to the pixel 10. The first photoelectric conversion element 101 is disposed corresponding to the left side of the microlens 110, and the second photoelectric conversion element 102 is disposed corresponding to the right side of the microlens 110. That is, the first photoelectric conversion element 101 and the second photoelectric conversion element 102 are disposed to receive light passing through areas different from each other in the pupil of an optical system. With this configuration, it is possible to perform phase difference detection using parallax signals different between the left and right. The first photoelectric conversion element 101 may be disposed corresponding to the upper side of the microlens 110, and the second photoelectric conversion element 102 may be disposed corresponding to the lower side of the microlens 110.

FIG. 4 is an example of a block diagram of the photoelectric conversion apparatus 1 according to the present exemplary embodiment. As an example, FIG. 4 illustrates pixels 10 corresponding to two pixels in the vertical direction (first and second rows from the top) and twelve pixels in the horizontal direction (first, second, . . . , and twelfth columns from the left) among the plurality of pixels 10 included in the pixel array 11. A control signal tx1[0] and a control signal tx2[0] indicate the control signal tx1 and the control signal tx2, respectively, supplied to the pixels 10 disposed in the first row. A control signal tx1[1] and a control signal tx2[1] indicate the control signal tx1 and the control signal tx2, respectively, supplied to the pixels 10 disposed in the second row.

As illustrated in FIG. 4, a first control line 134 that supplies the control signal tx1 to pixels 10 and the second control line 135 that supplies the control signal tx2 to the pixels 10 are disposed. With reference to FIG. 4, the connection relationships between the pixels 10, the first control line 134, and the second control line 135 are described. A connection portion 120 indicates that the first control line 134 is connected to the gate of the first transfer transistor 103 corresponding to the first photoelectric conversion element 101 disposed on the left side of a pixel 10. A connection portion 121 indicates that the second control line 135 is connected to the gate of the second transfer transistor 104 corresponding to the second photoelectric conversion element 102 disposed on the right side of the pixel 10. A connection portion 122 indicates that the second control line 135 is connected to the gate of the first transfer transistor 103 corresponding to the first photoelectric conversion element 101 disposed on the left side of a pixel 10. A connection portion 123 indicates that the first control line 134 is connected to the second photoelectric conversion element 102 disposed on the right side of the pixel 10. That is, among the pixels 10 disposed in the first row, the pixels 10 disposed in the first, second, fifth, sixth, ninth, and tenth columns are of the type A, and the pixels 10 disposed in the third, fourth, seventh, eighth, eleventh, and twelfth columns are of the type B.

Further, among the pixels 10 disposed in the second row, the pixels 10 disposed in the first, second, fifth, sixth, ninth, and tenth columns are of the type A, and the pixels 10 disposed in the third, fourth, seventh, eighth, eleventh, and twelfth columns are of the type B. In the present exemplary embodiment illustrated in FIG. 4, a configuration is employed in which pixels 10 disposed in the same column and different rows are of the same type, and pixels 10 of the type A and pixels 10 of the type B are alternately disposed every two columns. The pixels 10 disposed in the first row and the first column, the first row and the third column, the second row and the first column, the second row and the third column, and the first row and the second column are occasionally referred to as a “first pixel”, a “second pixel”, a “third pixel”, a “fourth pixel”, and a “fifth pixel”, respectively. The microlenses 110 disposed corresponding to the first to fifth pixels are occasionally referred to as a “first microlens”, a “second microlens”, a “third microlens”, a “fourth microlens”, and a “fifth microlens”, respectively. The FDs 109 included in the first to third pixels are occasionally referred to as a “first floating diffusion”, a “second floating diffusion”, and a “third floating diffusion”, respectively. The FDs 109 included in the fourth and fifth pixels are occasionally referred to as a “fourth floating diffusion” and a “fifth floating diffusion”, respectively. The first photoelectric conversion element 101 that generates a first charge and the second photoelectric conversion element 102 that generates a second charge that are included in the second pixel are occasionally referred to as “a third photoelectric conversion element that generates a third charge” and “a fourth photoelectric conversion element that generates a fourth charge”, respectively. The first transfer transistor 103 and the second transfer transistor 104 included in the second pixel are occasionally referred to as a “third transfer transistor” and a “fourth transfer transistor”, respectively. The first photoelectric conversion element 101 that generates a first charge and the second photoelectric conversion element 102 that generates a second charge that are included in the third pixel are occasionally referred to as “a fifth photoelectric conversion element that generates a fifth charge” and “a sixth photoelectric conversion element that generates a sixth charge”, respectively. The first transfer transistor 103 and the second transfer transistor 104 included in the third pixel are occasionally referred to as a “fifth transfer transistor” and a “sixth transfer transistor”, respectively. The first photoelectric conversion element 101 that generates a first charge and the second photoelectric conversion element 102 that generates a second charge that are included in the fourth pixel are occasionally referred to as “a seventh photoelectric conversion element that generates a seventh charge” and “an eighth photoelectric conversion element that generates an eighth charge”, respectively. The first transfer transistor 103 and the second transfer transistor 104 included in the fourth pixel are occasionally referred to as a “seventh transfer transistor” and an “eighth transfer transistor”, respectively. The first photoelectric conversion element 101 that generates a first charge and the second photoelectric conversion element 102 that generates a second charge that are included in the fifth pixel are occasionally referred to as “a ninth photoelectric conversion element that generates a ninth charge” and “a tenth photoelectric conversion element that generates a tenth charge”, respectively. The first transfer transistor 103 and the second transfer transistor 104 included in the fifth pixel are occasionally referred to as a “ninth transfer transistor” and a “tenth transfer transistor”, respectively. The first control line 134 and the second control line 135 corresponding to the pixels 10 disposed in the second row are occasionally referred to as a “third control line” and a “fourth control line”, respectively.

The AD conversion unit 14 is described. A form is described in which the AD conversion unit 14 is a circuit that performs slope AD conversion. The AD conversion unit 14 includes an AD conversion circuit 141 and a switch 142 corresponding to each of the columns in which the pixels 10 are disposed. Pixel signals output from the pixels 10 are input to the AD conversion circuits 141 via the output lines 108, and signals output from the AD conversion circuits 141 are input to the signal output circuit 15 via the switches 142. Pixel signals output from the pixels 10 disposed in the odd-numbered columns are input to the AD conversion unit 14 disposed above the pixel array 11. Pixel signals output from the pixels 10 disposed in the even-numbered columns are input to the AD conversion unit 14 disposed below the pixel array 11. For example, in a case where the AD conversion circuits 141 perform slope AD conversion, each AD conversion circuit 141 includes a comparator and a counter (the comparator and the counter are not illustrated). The comparator compares a pixel signal and a reference signal, and the counter holds a count value corresponding to the inversion timing of the comparator, whereby the AD conversion circuit 141 performs AD conversion. The AD conversion unit 14 disposed above the pixel array 11 has a configuration similar to that of the AD conversion unit 14 disposed below the pixel array 11, and therefore is not illustrated in FIG. 4.

The switches 142 corresponding to the first, fifth, and ninth columns are connected to a horizontal transfer line 143 (a channel chA), and the switches 142 corresponding to the third, seventh, and eleventh columns are connected to a horizontal transfer line 144 (a channel chB). The turning on and off of the switches 142 are controlled by a control signal hadr, and the turning on and off are sequentially controlled in the horizontal direction. Digital signals output from the AD conversion circuits 141 are input to the signal output circuit 15 via the horizontal transfer line 143 or the horizontal transfer line 144 when the switches 142 are on. Digital signals output from the AD conversion circuits 141 corresponding to the first, third, fifth, seventh, ninth, and eleventh columns are referred to as a “signal ado(0)” to a “signal ado(5)”, respectively. Control signals of the switches 142 corresponding to the first, third, fifth, seventh, ninth, and eleventh columns are referred to as a “control signal hadr(0)” to a “control signal hadr(5)”, respectively.

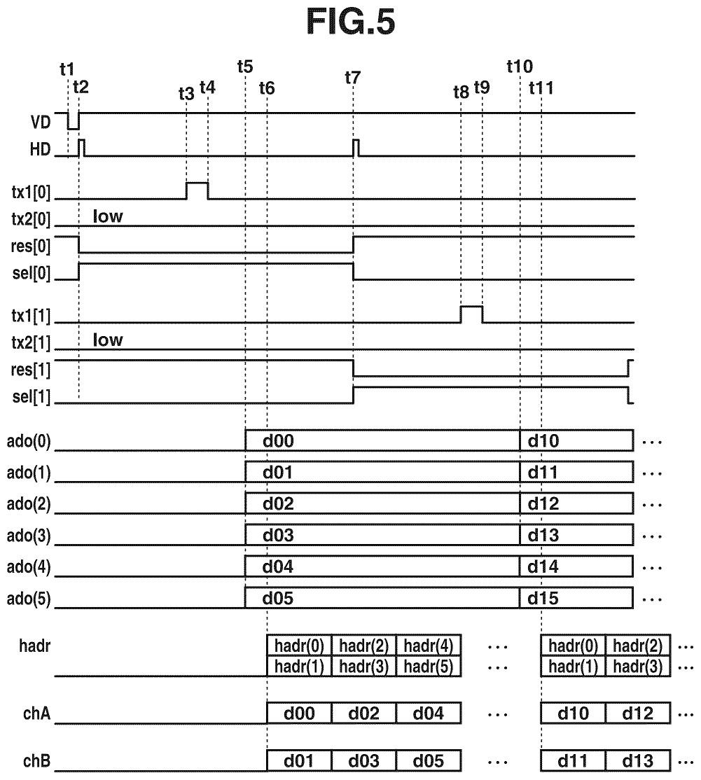

FIG. 5 is an example of a driving timing chart of the photoelectric conversion apparatus 1 according to the present exemplary embodiment. In the driving timing chart illustrated in FIG. 5, signals are not read from first photoelectric conversion elements 101 and second photoelectric conversion elements 102 in which oblique lines are drawn in FIG. 4.

In FIG. 5, the horizontal axis represents a time. FIG. 5 schematically illustrates the timings of driving pulses (control signals), digital values corresponding to digital signals, and digital values output to channels. The control signals illustrated in FIG. 5 correspond to the control signals illustrated in FIGS. 2A, 2B, and 4.

At a time t1, the vertical scanning circuit 12 sets a control signal VD (a vertical synchronization signal) to a low level, whereby a single frame starts. At a time t2, the vertical scanning circuit 12 sets a control signal HD (a horizontal synchronization signal) to a high level, whereby an operation for a single row starts. Further, at the time t2, the vertical scanning circuit 12 sets the control signal VD to a high level, a control signal res[0] to a low level, and a control signal sel[0] to a high level.

During the period from a time t3 to a time t4, the vertical scanning circuit 12 sets a control signal tx1[0] to a high level and maintains a control signal tx2[0] at a low level. [0] means a row address indicating the first row, and the same control signals are supplied to the plurality of pixels 10 disposed in the first row. As illustrated in FIG. 4, among the plurality of pixels 10 disposed in the first row, the pixels 10 of the type A disposed in the first, second, fifth, sixth, ninth, and tenth columns each output a pixel signal corresponding to the first photoelectric conversion element 101 disposed on the left side of the pixel 10. Among the pixels 10 disposed in the first row, the pixels 10 of the type B disposed in the third, fourth, seventh, eighth, eleventh, and twelfth columns each output a pixel signal corresponding to the second photoelectric conversion element 102 disposed on the right side of the pixel 10. Thus, the pixels 10 disposed in the first row each output a pixel signal corresponding to either one of the photoelectric conversion elements disposed on the left and right. At this time, the pixel signals output from the pixels 10 switch between pixel signals corresponding to first photoelectric conversion elements 101 and pixel signals corresponding to second photoelectric conversion elements 102 every two columns.

At a time t5, the AD conversion circuits 141 complete AD conversion and hold acquired digital values. A signal ado(0) to a signal ado(5) have a value d00 to a value d05, respectively, as digital values corresponding to the photoelectric conversion elements driven by the control signal tx1[0].

At a time t6, the timing signal output circuit 13 starts supplying a control signal hadr to the AD conversion unit 14, whereby the signals ado(0) to ado(5) are sequentially output. In the first cycle, a control signal hadr(0) and a control signal hadr(1) are input to switches 142. In the second cycle, a control signal hadr(2) and a control signal hadr(3) are input to switches 142. In the third cycle, a control signal hadr(4) and a control signal hadr(5) are input to switches 142. As a result, the values d00, d02, and d04 are sequentially output to the horizontal transfer line 143 (the channel chA), and the values d01, d03, and d05 are sequentially output to the horizontal transfer line 144 (the channel chB). Thus, a signal corresponding to the first photoelectric conversion element 101 disposed on the left side of each pixel 10 is output to the channel chA, and a signal corresponding to the second photoelectric conversion element 102 disposed on the right side of each pixel 10 is output to the channel chB.

The driving performed on the pixels 10 disposed in the first row during the period from the time t2 to the time t6 is performed next on the pixels 10 disposed in the second row during the period from a time t7 to a time t11.

At the time t7, the reading of the signals corresponding to the pixels 10 in the first row may not be completed, and the reading of the signals corresponding to the pixels 10 in the first row and control of the pixels 10 in the second row may be processed in parallel. The reason is as follows. Since the signals corresponding to the pixels 10 in the first row are read based on information held in the AD conversion circuits 141, in one embodiment, the reading of the signals corresponding to the pixels 10 in the first row only needs to be completed by the time when digital signals corresponding to the pixels 10 in the second row are held in the AD conversion circuits 141.

At the time t7, the vertical scanning circuit 12 sets the control signal HD to the high level, whereby an operation for a single row starts. Further, at the time t7, the vertical scanning circuit 12 sets the control signal res[0] to a high level, the control signal sel[0] to a low level, a control signal res[1] to a low level, and a control signal sel[1] to a high level.

During the period from the time t8 to the time t9, the vertical scanning circuit 12 sets a control signal tx1[1] to a high level and maintains a control signal tx2[1] at a low level. [1] means a row address indicating the second row, and the same control signals are supplied to the plurality of pixels 10 disposed in the second row. As illustrated in FIG. 4, among the plurality of pixels 10 disposed in the second row, the pixels 10 of the type A disposed in the first, second, fifth, sixth, ninth, and tenth columns each output a pixel signal corresponding to the first photoelectric conversion element 101 disposed on the left side of the pixel 10. Among the pixels 10 disposed in the second row, the pixels 10 of the type B disposed in the third, fourth, seventh, eighth, eleventh, and twelfth columns each output a pixel signal corresponding to the second photoelectric conversion element 102 disposed on the right side of the pixel 10. Thus, the pixels 10 disposed in the second row each output a pixel signal corresponding to either one of the photoelectric conversion elements disposed on the left and right. At this time, the pixel signals output from the pixels 10 switch between pixel signals corresponding to first photoelectric conversion elements 101 and pixel signals corresponding to second photoelectric conversion elements 102 every two columns.

At the time t10, the AD conversion circuits 141 complete AD conversion and hold acquired digital values. The signals ado(0) to ado(5) have a value d10 to a value d15, respectively, as digital values corresponding to the photoelectric conversion elements driven by the control signal tx1[1]. By the time t10, the reading of the digital signals corresponding to the pixels 10 disposed in the first row is completed.

At the time t11, the timing signal output circuit 13 starts supplying the control signal hadr to the AD conversion unit 14, whereby the signals ado(0) to ado(5) are sequentially output. In the first cycle, the control signals hadr(0) and hadr(1) are input to switches 142. In the second cycle, the control signals hadr(2) and hadr(3) are input to switches 142. In the third cycle, the control signals hadr(4) and hadr(5) are input to switches 142. As a result, the values d10, d12, and d14 are sequentially output to the horizontal transfer line 143 (the channel chA), and the values d11, d13, and d15 are sequentially output to the horizontal transfer line 144 (the channel chB). Thus, a signal corresponding to the first photoelectric conversion element 101 disposed on the left side of each pixel 10 is output to the channel chA, and a signal corresponding to the second photoelectric conversion element 102 disposed on the right side of each pixel 10 is output to the channel chB.

The above driving is performed with respect to each row, and signals corresponding to all the pixels 10 are read, thereby completing the driving of a single frame.

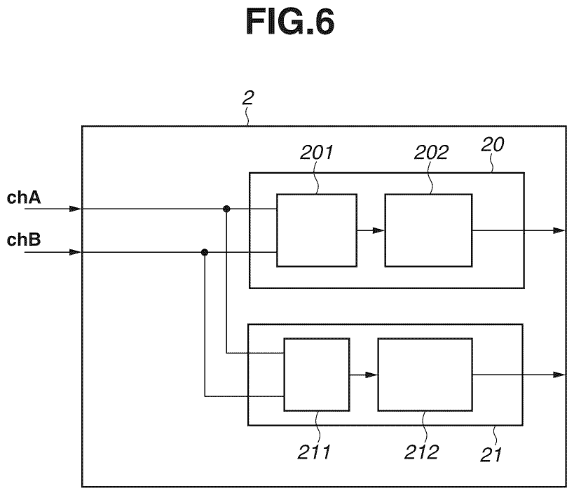

FIG. 6 is an example of a block diagram of the signal correction circuit 2 according to the present exemplary embodiment.

As illustrated in FIG. 6, the signal correction circuit 2 includes the focus detection circuit 20 and the image generation circuit 21. Signals corresponding to the first photoelectric conversion elements 101 input to the channel chA and signals corresponding to the second photoelectric conversion elements 102 input to the channel chB are input to the focus detection circuit 20 and the image generation circuit 21.

The focus detection circuit 20 includes a peak detection circuit 201 and a phase difference detection circuit 202. The peak detection circuit 201 performs peak detection on signals sequentially input via the channel chA. Further, the peak detection circuit 201 performs peak detection on signals sequentially input via the channel chB. The phase difference detection circuit 202 compares the peak positions of the signals sequentially input via the channel chA and the peak positions of the signals sequentially input via the channel chB that are detected by the peak detection circuit 201. As a result, the phase difference detection circuit 202 detects whether an object is in focus, in front focus, or in back focus.

The image generation circuit 21 includes an addition circuit 211 and a generation circuit 212. The addition circuit 211 adds signals sequentially input via the channels chA and chB in the input order. Thus, in FIG. 4, a signal corresponding to the first photoelectric conversion element 101 disposed on the left side of a pixel 10 in the first column and a signal corresponding to the second photoelectric conversion element 102 disposed on the right sides of a pixel 10 in the third column are added (horizontally added) together. Using a signal obtained by the addition by the addition circuit 211, the generation circuit 212 performs noise removal and a filter process and suitably corrects a display system or a recording system.

In the present exemplary embodiment, it is possible to perform image generation using signals output from a plurality of pixels 10 in a single frame and focus detection using the same signals. For example, in this configuration, a moving image is suitably captured while a distance is measured.

Although color filters are not illustrated, a configuration is considered in which color filters in the Bayer arrangement are disposed. For example, among the pixels 10 disposed in the first row, red color filters are disposed corresponding to the pixels 10 disposed in the odd-numbered columns, and green color filters are disposed corresponding to the pixels 10 disposed in the even-numbered columns. Among the pixels 10 disposed in the second row, green color filters are disposed corresponding to the pixels 10 disposed in the odd-numbered columns, and blue color filters are disposed corresponding to the pixels 10 disposed in the even-numbered columns. In this configuration, signals added together by the addition circuit 211 are output from pixels 10 in which color filters of the same color are disposed. Thus, the addition circuit 211 can add signals of two pixels in which color filters of the same color are disposed and which are disposed in the same row.

Although the present exemplary embodiment has been described using an example where vertical scanning is performed by selecting each row, vertical scanning may be performed by simultaneously selecting two rows, namely the first and third rows. In this case, the pixels 10 disposed in the first and third rows are connected to a single output line 108, whereby signals output from the pixels 10 disposed in the first and third rows can be added (vertically added) together. With this configuration, signals output from two pixels 10 in each of the horizontal direction and the vertical direction, i.e., a total of four pixels 10, can be added (horizontally and vertically added) together. In the above configuration in which color filters in the Bayer arrangement are disposed, since color filters of the same color are disposed in four pixels 10 in which horizontal and vertical addition is performed, it is possible to perform horizontal and vertical addition using signals corresponding to the same color.

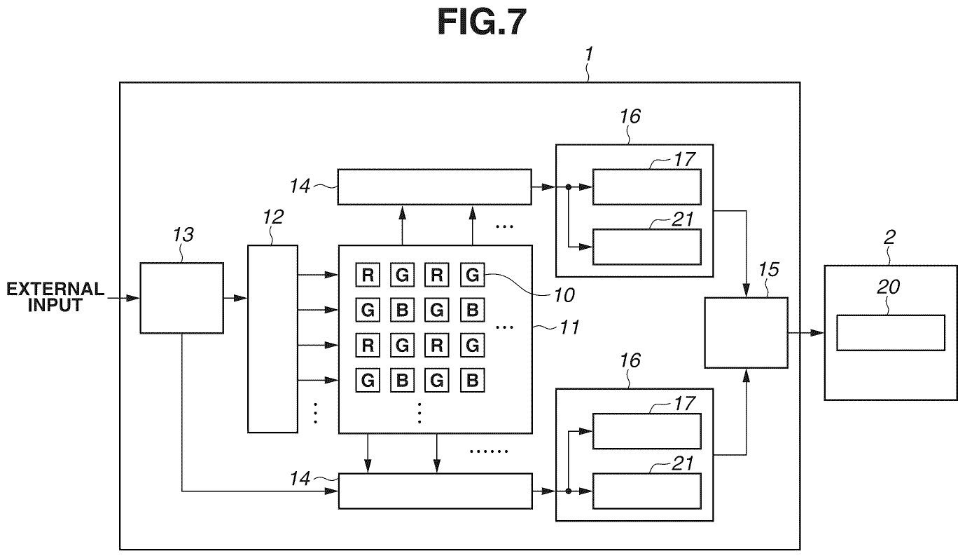

With reference to FIG. 7 to FIGS. 9A, 9B, and 9C, a photoelectric conversion apparatus 1 (a signal processing method for a photoelectric conversion apparatus) according to a second exemplary embodiment of the disclosure is described. Components similar to those in the first exemplary embodiment are designated by the same signs, and the description of these components is occasionally omitted or simplified.

The second exemplary embodiment is different from the first exemplary embodiment in that the photoelectric conversion apparatus 1 includes a processing circuit 16. FIG. 7 is an example of a block diagram of the photoelectric conversion apparatus 1 according to the present exemplary embodiment.

As illustrated in FIG. 7, the photoelectric conversion apparatus 1 includes a pixel array 11, a vertical scanning circuit 12, a timing signal output circuit 13, an AD conversion unit 14, a signal output circuit 15, and a processing circuit 16. A signal correction circuit 2 includes a focus detection circuit 20. FIG. 7 illustrates a form in which the signal correction circuit 2 is disposed outside the photoelectric conversion apparatus 1. Typically, a form is employed in which the signal correction circuit 2 is provided on a chip different from a chip on which the photoelectric conversion apparatus 1 is formed. The present exemplary embodiment is not limited to this form, and the signal correction circuit 2 may be disposed inside the photoelectric conversion apparatus 1.

The processing circuit 16 includes a compression circuit 17 and an image generation circuit 21. The compression circuit 17 performs a compression process on a phase difference signal for focus detection. Digital signals held in the AD conversion unit 14 are sequentially transferred to the processing circuit 16 via a channel chA and a channel chB. The processing circuit 16 processes signals sequentially input by horizontal scanning.

The signal correction circuit 2 performs focus detection by changing processes according to a signal compressed by the compression circuit 17. Further, using a signal output from the image generation circuit 21, the signal correction circuit 2 performs noise removal and a filter process and suitably corrects a display system or a recording system. In the present exemplary embodiment, not the signal correction circuit 2 but the photoelectric conversion apparatus 1 includes the image generation circuit 21.

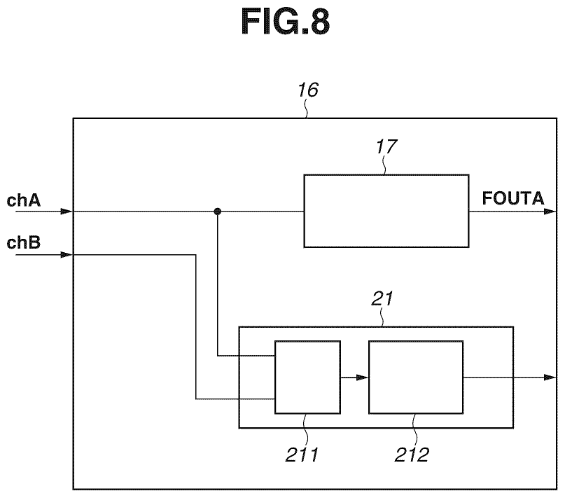

FIG. 8 is an example of a block diagram of the processing circuit 16 included in the photoelectric conversion apparatus 1 according to the present exemplary embodiment.

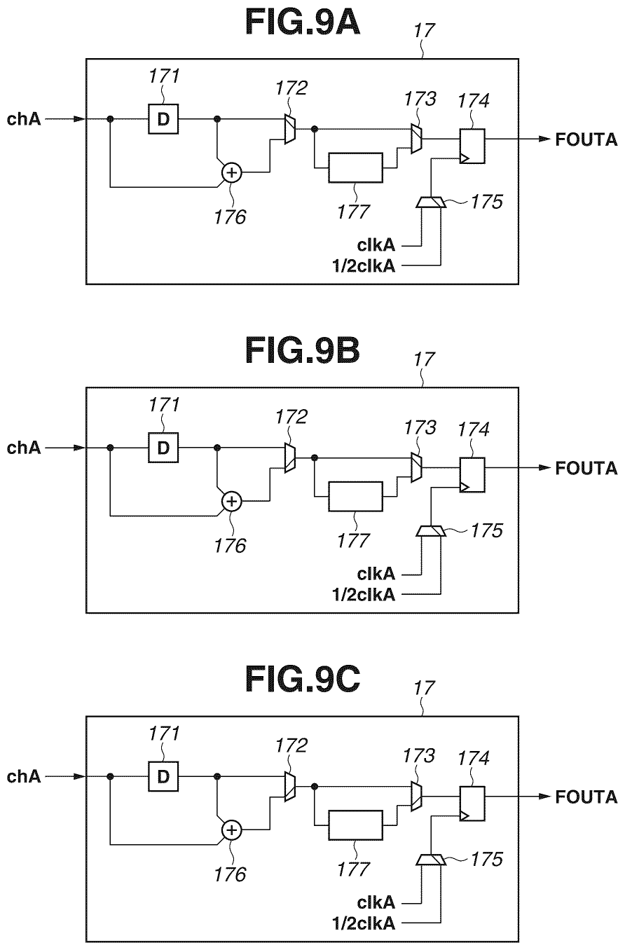

As illustrated in FIG. 8, the image generation circuit 21 includes an addition circuit 211 and a generation circuit 212. The addition circuit 211 adds signals sequentially input via the channels chA and chB in the input order. Using a signal obtained by the addition by the addition circuit 211, the generation circuit 212 performs a gain process and a clamp process. In the present exemplary embodiment, the signal correction circuit 2 performs the suitable correction process on the display system or the recording system. Thus, the generation circuit 212 performs preprocessing necessary for the signal correction circuit 2 at a subsequent stage to perform the correction process. The compression circuit 17 included in the processing circuit 16 illustrated in FIG. 8 is described below with reference to FIGS. 9A, 9B, and 9C.

FIGS. 9A, 9B, and 9C are examples of circuit diagrams of the compression circuit 17 included in the photoelectric conversion apparatus 1 according to the present exemplary embodiment. To the compression circuit 17 according to the present exemplary embodiment, a signal corresponding to the channel chB is not input, and a signal corresponding to the channel chA is input. FIGS. 9A, 9B, and 9C illustrate different types of driving in the same circuit configuration.

FIG. 9A illustrates driving for thinning a signal for a single pixel between sequentially input signals for two pixels corresponding to the channel chA. As illustrated in FIG. 9A, an input signal corresponding to the channel chA is delayed by one cycle by a D-latch circuit 171 and then input to a flip-flop circuit 174 via multiplexer circuits 172 and 173. To the flip-flop circuit 174, a clock signal 1/2clkA is input via a multiplexer circuit 175. The clock signal 1/2clkA is a clock signal corresponding to a clock signal clkA in a half cycle. By this driving, a signal for a single pixel between sequentially input signals for two pixels corresponding to the channel chA is output as a signal FOUTA.

FIG. 9B illustrates driving for adding sequentially input signals for two pixels corresponding to the channel chA and outputting the resulting signal. As illustrated in FIG. 9B, an adder 176 adds signals at a previous stage and a subsequent stage of the D-latch circuit 171. The multiplexer circuit 172 outputs a signal obtained by the addition by the adder 176. The driving of circuits at subsequent stages of the multiplexer circuit 172 is similar to that in FIG. 9A. By this driving, a signal obtained by adding sequentially input signals for two pixels corresponding to the channel chA is output as a signal FOUTA.

FIG. 9C illustrates driving for, in addition to the driving for performing the addition process on signals for two pixels that is illustrated in FIG. 9B, further deleting lower bits of (performing a number-of-bits reduction process on) a signal (a digital signal) obtained by the addition. As illustrated in FIG. 9C, a bit deletion circuit 177 performs the process of deleting lower bits of a signal output from the multiplexer circuit 172. A signal output from the bit deletion circuit 177 is input to the flip-flop circuit 174 via the multiplexer circuit 173. The driving of circuits at subsequent stages of the multiplexer circuit 173 is similar to that in FIG. 9A.

The driving of circuits at previous stages of the multiplexer circuit 172 is similar to that in FIG. 9B. By this driving, a signal obtained by adding sequentially input signals for two pixels corresponding to the channel chA is output as a signal FOUTA in the state where lower bits of the signal are deleted.

For example, the compression circuit 17 according to the present exemplary embodiment has the circuit configuration illustrated in FIGS. 9A, 9B, and FIG. 9C, performs the driving illustrated in FIGS. 9A, 9B, and FIG. 9C, and compresses a phase difference signal for focus detection. The compression circuit 17 may have the circuit configuration illustrated in FIGS. 9A, 9B, and FIG. 9C and switch the driving illustrated in FIGS. 9A, 9B, and FIG. 9C according to operation modes. In a case where the compression circuit 17 performs the driving illustrated in FIG. 9A, the compression circuit 17 may not include components that are not necessarily required for the driving described with reference to FIG. 9A. In a case where the compression circuit 17 performs the driving illustrated in FIG. 9B, the compression circuit 17 may not include components that are not necessarily required for the driving described with reference to FIG. 9B. In one embodiment, not only the circuit configuration and the driving but also the various data compression methods illustrated in FIGS. 9A, 9B, and 9C can be applied to only a phase difference signal. The data compression can be applied not only to a phase difference signal for focus detection but also to a signal for image generation. In this case, it is desirable that the compression ratio of the phase difference signal is higher than that of the signal for the image generation.

The signal correction circuit 2 subtracts a signal corresponding to the channel chA output from the compression circuit 17 from signals corresponding to the channels chA and chB output from the image generation circuit 21. By this subtraction process, the signal correction circuit 2 generates a signal corresponding to the channel chB. Then, using the signal corresponding to the channel chA and the signal corresponding to the channel chB, the signal correction circuit 2 performs peak detection and phase difference detection and performs focus detection.

In the present exemplary embodiment, it is possible to perform image generation using signals output from a plurality of pixels 10 in a single frame and focus detection using the same signals. For example, in this configuration, a moving image is suitably captured while a distance is measured.

Further, in the present exemplary embodiment, by using the compression circuit 17, it is possible to reduce the data bandwidth in the photoelectric conversion apparatus 1 and a photoelectric conversion system including the photoelectric conversion apparatus 1. Thus, it is possible to reduce the load on the signal correction circuit 2.

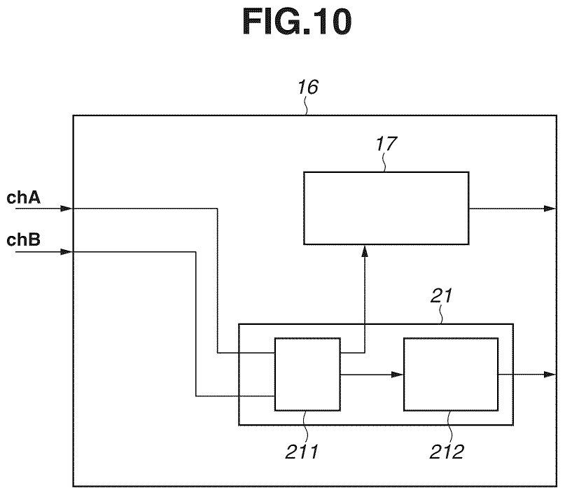

With reference to FIGS. 10 to 14, a photoelectric conversion apparatus 1 (a signal processing method for a photoelectric conversion apparatus) according to a third exemplary embodiment of the disclosure is described. Components similar to those in the first and second exemplary embodiments are designated by the same signs, and the description of these components is occasionally omitted or simplified.

The third exemplary embodiment is different from the first exemplary embodiment in that the photoelectric conversion apparatus 1 includes a processing circuit 16, and is different from the second exemplary embodiment in the configuration of the processing circuit 16. FIG. 10 is an example of a block diagram of the processing circuit 16 included in the photoelectric conversion apparatus 1 according to the present exemplary embodiment.

As illustrated in FIG. 10, the processing circuit 16 includes a compression circuit 17 and an image generation circuit 21.

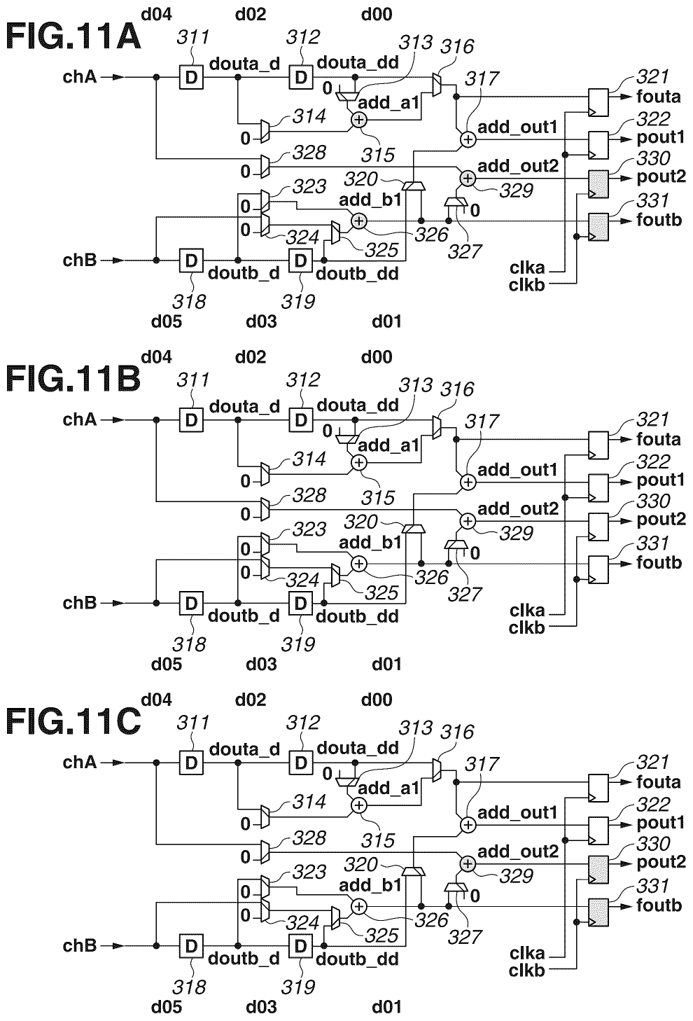

The image generation circuit 21 includes an addition circuit 211 and a generation circuit 212. The addition circuit 211 adds signals sequentially input via a channel chA and a channel chB in the input order. Using a signal obtained by the addition by the addition circuit 211, the generation circuit 212 performs a gain process and a clamp process. To the compression circuit 17, a signal output from the addition circuit 211 is input. The addition circuit 211 included in the image generation circuit 21 illustrated in FIG. 10 is described below with reference to FIGS. 11A, 11B, and 11C.

FIGS. 11A, 11B, and 11C are examples of circuit diagrams of the addition circuit 211 included in the photoelectric conversion apparatus 1 according to the present exemplary embodiment. FIGS. 11A, 11B, and 11C illustrate different types of driving in the same circuit configuration.

FIG. 11A illustrates driving for adding (horizontally adding) pixel signals output from two pixels 10 disposed in the same row.

As illustrated in FIG. 11A, an input signal corresponding to the channel chA is delayed by two clocks by a D-latch circuit 311 and a D-latch circuit 312 and then input to an adder 317 via a multiplexer circuit 316. Further, the signal corresponding to the channel chA and passing through the multiplexer circuit 316 is also input to a flip-flop circuit 321 in addition to the adder 317. An input signal corresponding to the channel chB is delayed by two clocks by a D-latch circuit 318 and a D-latch circuit 319 and then input to the adder 317 via a multiplexer circuit 320. The signal corresponding to the channel chA and the signal corresponding to the channel chB that are input at the same timing are added together by the adder 317, and the resulting signal is input to a flip-flop circuit 322. The signals input to the flip-flop circuits 321 and 322 are output as a signal fouta and a signal pout1, respectively, using a clock signal clka. By this driving, a signal for a single pixel corresponding to the channel chA is output as the signal fouta. A signal obtained by adding the signal for the single pixel corresponding to the channel chA and a signal for a single pixel corresponding to the channel chB is output as the signal pout1.

In the addition driving illustrated in FIG. 11A, adders 315, 326, and 329 are controlled to output 0. At this time, multiplexer circuits 313, 314, 323, 324, 327, and 328 are controlled to output input 0 so that the adders 315, 326, and 329 output 0. By this driving, signals output from the adders 315, 326, and 329 remain unchanged as 0. Thus, it is possible to reduce power consumption. A clock signal clkb input to flip-flop circuits 330 and 331 may be fixed to a low level. In this case, it is possible to further reduce power consumption in the flip-flop circuits 330 and 331.

FIG. 11B illustrates driving for adding (horizontally adding) pixel signals output from three pixels 10 disposed in the same row. FIG. 11B is different from FIG. 11A in that each multiplexer circuit does not output input 0.

As illustrated in FIG. 11B, the multiplexer circuit 313 is controlled to output a signal douta_dd, the multiplexer circuit 314 is controlled to output a signal douta_d, and the multiplexer circuit 328 is controlled to output a signal corresponding to the channel chA. The multiplexer circuit 323 is controlled to output a signal doutb_d, the multiplexer circuit 324 is controlled to output a signal corresponding to the channel chB, and the multiplexer circuit 327 is controlled to output a signal add_b1. By this driving, a signal obtained by adding sequentially input signals for two pixels corresponding to the channel chA are output as a signal fouta. A signal obtained by adding sequentially input signals for two pixels corresponding to the channel chB are also output as a signal foutb. The signal obtained by adding the sequentially input signals for the two pixels corresponding to the channel chA and a signal for a single pixel corresponding to the channel chB is output as a signal pout1. The signal obtained by adding the sequentially input signals for the two pixels corresponding to the channel chB and a signal for a single pixel corresponding to the channel chA is output as a signal pout2.

In the addition driving illustrated in FIG. 11B, the adders 315, 326, and 329, of which the outputs are fixed in FIG. 11A, can output signals that change in response to the results of the addition processes. A clock signal clkb, which is fixed to the low level in FIG. 11A, performs a clock operation at the same frequency as that of a clock signal clka.

FIG. 11C illustrates driving for adding (horizontally adding) pixel signals output from four pixels 10 disposed in the same row. FIG. 11C is different from FIG. 11B in control of the multiplexer circuit 320, a multiplexer circuit 325, the multiplexer circuit 327, and the multiplexer circuit 328. Similarly to FIG. 11A, the multiplexer circuits 327 and 328 are controlled to output 0.

As illustrated in FIG. 11C, the multiplexer circuit 320 outputs a signal add_b1, and the multiplexer circuit 325 outputs a signal doutb_dd. The adder 326 adds a signal doutb_d and the signal doutb_dd, and the adder 317 adds a signal add_a1 and the signal add_b1. Then, the flip-flop circuit 321 outputs the signal add_a1 as a signal fouta, and the flip-flop circuit 322 outputs a signal add_out1 as a signal pout1. By this driving, signals for two pixels corresponding to the channel chA are output as the signal fouta. A signal obtained by adding the signals for the two pixels corresponding to the channel chA and signals for two pixels corresponding to the channel chB is output as the signal pout1.

In the addition driving illustrated in FIG. 11C, a signal output from the adder 329 is controlled to remain unchanged as 0. By this driving, it is possible to reduce power consumption. A clock signal clkb input to the flip-flop circuits 330 and 331 may be fixed to a low level. In this case, it is possible to further reduce power consumption in the flip-flop circuits 330 and 331.

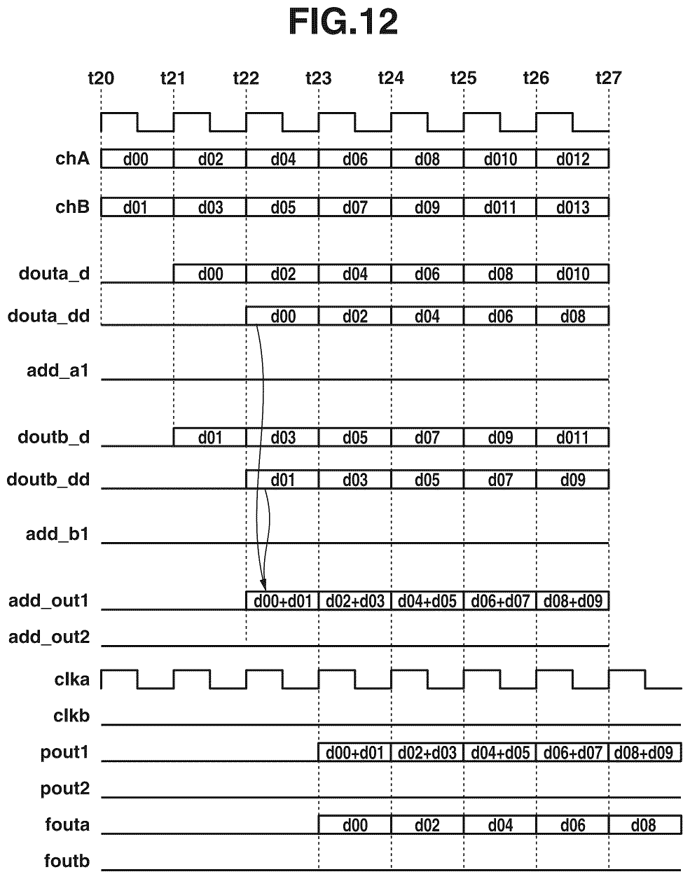

FIG. 12 is an example of a driving timing chart of the photoelectric conversion apparatus 1 according to the present exemplary embodiment. FIG. 12 illustrates the driving for adding (horizontally adding) pixel signals output from two pixels 10 disposed in the same row that is described with reference to FIG. 11A.

In FIG. 12, the horizontal axis represents a time. FIG. 12 schematically illustrates the timings of driving pulses (control signals), digital values corresponding to digital signals, and digital values output to channels. The control signals illustrated in FIG. 12 correspond to the control signals illustrated in FIGS. 2A, 2B, 4, and 11A.

At a time t20, lead signals corresponding to the channels chA and chB are input to the addition circuit 211. The lead signal corresponding to the channel chA has a value d00, and the lead signal corresponding to the channel chB has a value d01.

At a time t21, a signal douta_d output from the D-latch circuit 311 has the value d00, and a signal doutb_d output from the D-latch circuit 311 has the value d01.

At a time t22, a signal douta_dd output from the D-latch circuit 312 has the value d00, and a signal doutb_dd output from the D-latch circuit 319 has the value d01. At the time t22, as illustrated in FIG. 11A, the signal douta_dd is input to the adder 317 via the multiplexer circuit 316, and the signal doutb_dd is input to the adder 317 via the multiplexer circuit 320. The adder 317 adds the signals douta_dd and doutb_dd, and the adder 317 outputs the value d00+the value d01 as a signal add_out1.

At a time t23, the flip-flop circuit 321 outputs the signal douta_dd as a signal fouta. That is, at the time t23, the flip-flop circuit 321 outputs the value d00 as the signal fouta. At the time t23, the flip-flop circuit 322 outputs the signal add_out1 as a signal pout1. That is, at the time t23, the flip-flop circuit 322 outputs the value d00+the value d01 as the signal pout1.

Processing similar to the above processing executed from the time t20 to the time t23 is also executed from the time t21 to a time t24 using different signals input to the addition circuit 211 via the channels chA and chB. Further, also at and after the time t22, similar processing is sequentially executed.

Two signals input to each of the adders 315, 326, and 329 are fixed to 0. Thus, a signal add_a1, a signal add_b1, and a signal add_out2 output from the adders 315, 326, and 329, respectively, are fixed to 0. Further, a clock signal clkb is fixed to a low level, and therefore, a signal pout2 output from the flip-flop circuit 330 and a signal foutb output from the flip-flop circuit 331 are also fixed to low levels.

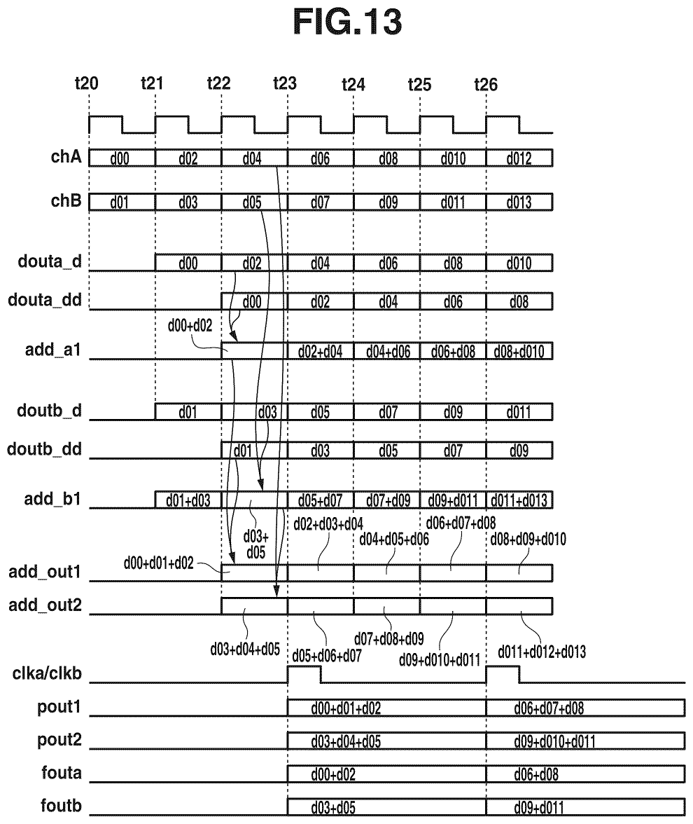

FIG. 13 is an example of a driving timing chart of the photoelectric conversion apparatus 1 according to the present exemplary embodiment. FIG. 13 illustrates the driving for adding (horizontally adding) pixel signals output from three pixels 10 disposed in the same row that is described with reference to FIG. 11B.

In FIG. 13, the horizontal axis represents a time. FIG. 13 schematically illustrates the timings of driving pulses (control signals), digital values corresponding to digital signals, and digital values output to channels. The control signals illustrated in FIG. 13 correspond to the control signals illustrated in FIGS. 2A, 2B, 4, and 11B.

At a time t20, lead signals corresponding to the channels chA and chB are input to the addition circuit 211. The lead signal corresponding to the channel chA has a value d00, and the lead signal corresponding to the channel chB has a value d01.

At a time t21, a signal douta_d output from the D-latch circuit 311 has the value d00, and a signal doutb_d output from the D-latch circuit 311 has the value d01.

At a time t22, a signal douta_dd output from the D-latch circuit 312 has the value d00, and a signal doutb_dd output from the D-latch circuit 319 has the value d01.

At the time t22, as illustrated in FIG. 11B, the signal douta_d is input to the adder 315 via the multiplexer circuit 314, and the signal douta_dd is input to the adder 315 via the multiplexer circuit 313. The adder 315 adds the signals douta_d and douta_dd, and the adder 315 outputs the value d00+a value d02 as a signal add_a1. At the time t22, as illustrated in FIG. 11B, the signal doutb_d is input to the adder 326 via the multiplexer circuit 323, and a signal input from the channel chB is input to the adder 326 via the multiplexer circuit 324. The adder 326 adds the signal doutb_d and the signal input from the channel chB, and the adder 326 outputs a value d03+a value d05 as a signal add_b1.

At the time t22, the adder 317 adds the signals add_a1 and doutb_dd, and the adder 317 outputs the value d00+the value d01+the value d02 as a signal add_out1. At the time t22, the adder 329 adds the signal add_b1 and a signal input from the channel chA, and the adder 329 outputs the value d03+a value d04+the value d05 as a signal add_out2.

At a time t23, the flip-flop circuit 321 outputs the signal add_a1 as a signal fouta. That is, at the time t23, the flip-flop circuit 321 outputs the value d00+the value d02 as the signal fouta. At the time t23, the flip-flop circuit 322 outputs the signal add_out1 as a signal pout1. That is, at the time t23, the flip-flop circuit 322 outputs the value d00+the value d01+the value d02 as the signal pout1. At the time t23, the flip-flop circuit 330 outputs the signal add_out2 as a signal pout2. That is, at the time t23, the flip-flop circuit 330 outputs the value d03+the value d04+the value d05 as the signal pout2. At the time t23, the flip-flop circuit 331 outputs the signal add_b1 as a signal foutb. That is, at the time t23, the flip-flop circuit 330 outputs the value d03+the value d05 as the signal foutb.

The signals output as the signals fouta and foutb are obtained by adding signals output from not three pixels but two pixels. The reason is as follows. The signals fouta and foutb are used as signals for focus detection in processing at a subsequent stage, and therefore, it is not desirable to add an output from the photoelectric conversion element on a different side. That is, each of the signals fouta and foutb is not obtained by adding a signal corresponding to the channel chA and a signal corresponding to the channel chB.

In FIG. 13, at the time t23 and a time t26, a clock signal clka and a clock signal clkb shift from low levels to high levels. That is, the clock signals clka and clkb are driven at a frequency that is one-third of the frequency of the clock signal clka in FIG. 12. Consequently, signals for three cycles are accumulated, and the adder 317 ultimately adds signals for three pixels. Thus, the clock signals clka and clkb are driven at a frequency that is one-third compared to the frequency of an input clock for shifting from a low level to a high level at timings such as the times t20, t21, t22, and t23.

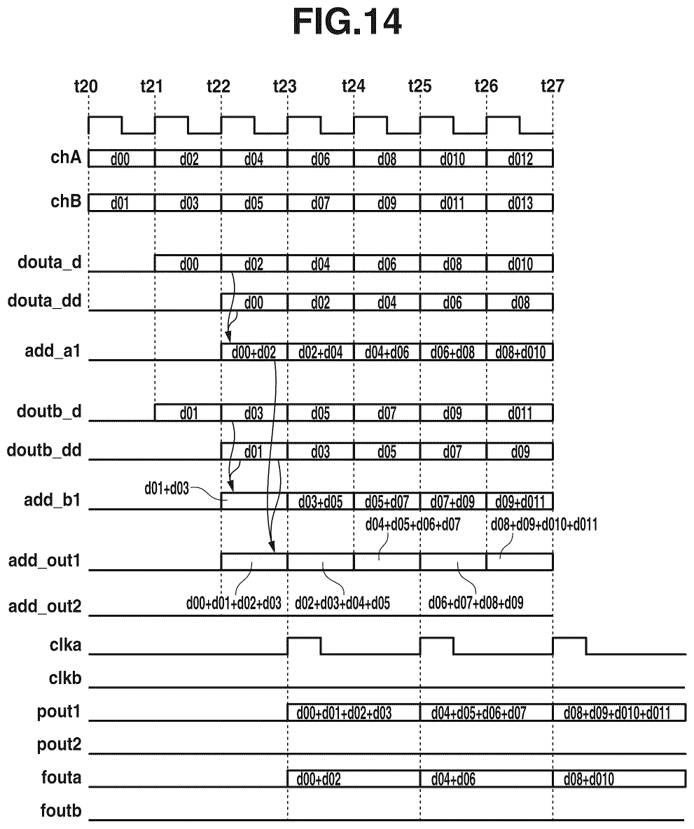

FIG. 14 is an example of a driving timing chart of the photoelectric conversion apparatus 1 according to the present exemplary embodiment. FIG. 14 illustrates the driving for adding (horizontally adding) pixel signals output from four pixels 10 disposed in the same row that is described with reference to FIG. 11C.

In FIG. 14, the horizontal axis represents a time. FIG. 14 schematically illustrates the timings of driving pulses (control signals), digital values corresponding to digital signals, and digital values output to channels. The control signals illustrated in FIG. 14 correspond to the control signals illustrated in FIGS. 2A, 2B, 4, and 11C.

At a time t20, lead signals corresponding to the channels chA and chB are input to the addition circuit 211. The lead signal corresponding to the channel chA has a value d00, and the lead signal corresponding to the channel chB has a value d01.

At a time t21, a signal douta_d output from the D-latch circuit 311 has the value d00, and a signal doutb_d output from the D-latch circuit 311 has the value d01.

At a time t22, a signal douta_dd output from the D-latch circuit 312 has the value d00, and a signal doutb_dd output from the D-latch circuit 319 has the value d01.

At the time t22, as illustrated in FIG. 11C, the signal douta_d is input to the adder 315 via the multiplexer circuit 314, and the signal douta_dd is input to the adder 315 via the multiplexer circuit 313. The adder 315 adds the signals douta_d and douta_dd, and the adder 315 outputs the value d00+a value d02 as a signal add_a1. At the time t22, as illustrated in FIG. 11C, the signal doutb_d is input to the adder 326 via the multiplexer circuit 323, and the signal doutb_dd is input to the adder 326 via the multiplexer circuit 325. The adder 326 adds the signals doutb_d and doutb_dd, and the adder 326 outputs the value d01+a value d03 as a signal add_b1.

At the time t22, the adder 317 adds the signals add_a1 and add_b1, and the adder 317 outputs the value d00+the value d01+the value d02+the value d03 as a signal add_out1.

At a time t23, the flip-flop circuit 321 outputs the signal add_a1 as a signal fouta. That is, at the time t23, the flip-flop circuit 321 outputs the value d00+the value d02 as the signal fouta. At the time t23, the flip-flop circuit 322 outputs the signal add_out1 as a signal pout1. That is, at the time t23, the flip-flop circuit 322 outputs the value d00+the value d01+the value d02+the value d03 as the signal pout1.

A clock signal clkb is fixed to a low level, and therefore, a signal pout2 output from the flip-flop circuit 330 and a signal foutb output from the flip-flop circuit 331 are also fixed to low levels.

In FIG. 14, at the time t23, a time t25, and a time t27, a clock signal clka shifts from a low level to a high level, and the flip-flop circuits 321 and 322 are driven. That is, the clock signal clka is driven at a frequency that is one-half of the frequency of the clock signal clka in FIG. 12. Consequently, signals for two cycles are accumulated in each of two branches, namely the channels chA and chB, and the adder 317 ultimately adds signals for four pixels. Thus, the clock signal clka is driven at a frequency that is one-half compared to the frequency of an input clock for shifting from a low level to a high level at timings such as the times t20, t21, t22, and t23.

As described above, with the circuit configuration of the addition circuit 211 illustrated in FIGS. 11A, 11B, and 11C, it is possible to achieve two-pixel addition, three-pixel addition, and four-pixel addition. Each multiplexer circuit included in the addition circuit 211 can be switched by a signal output from the timing signal output circuit 13. The driving of two-pixel addition, three-pixel addition, and four-pixel addition may be switched according to a plurality of operation modes included in the photoelectric conversion apparatus 1.

Signals fouta and foutb output from the addition circuit 211 and used in phase difference detection may be compressed by the compression circuit 17 as illustrated in the second exemplary embodiment. In this case, it is possible to reduce the load on the signal correction circuit 2.

Signals pout1 and pout2 output from the addition circuit 211 and used in image generation may be subjected to only necessary processes such as a gain process and a clamp process as preprocessing for the signal correction circuit 2 at a subsequent stage by the generation circuit 212 as illustrated in the second exemplary embodiment. In this case, correction suitable for a display system and a recording system is performed by the signal correction circuit 2.

Although in the present exemplary embodiment, horizontal two-pixel addition to horizontal four-pixel addition have been illustrated, it is possible to perform two-pixel addition, three-pixel addition, and four-pixel addition also in the vertical direction by changing the number of rows to be simultaneously selected in the vertical scanning circuit 12 that performs vertical scanning similarly to the first exemplary embodiment. In this case, a plurality of pixels 10 disposed in a plurality of rows is simultaneously connected to a single output line 108, and therefore, simulated vertical addition is performed. In this manner, it is possible to achieve the operations of two-pixel addition, three-pixel addition, and four-pixel addition in both the vertical direction and the horizontal direction.

As described above, two-pixel addition, three-pixel addition, and four-pixel addition of the same color are switched by driving in a single frame, whereby it is possible to perform focus detection using the same signals as those for image generation.

Consequently, for example, it is possible to optimally capture a moving image while measuring a distance.

A signal for focus detection can be compressed by the compression circuit 17, and additionally, the number of signals for image generation can be reduced by adding signals for a plurality of pixels. Thus, it is possible to reduce the data bands in a photoelectric conversion system. Thus, it is possible to reduce the load on the signal correction circuit 2.

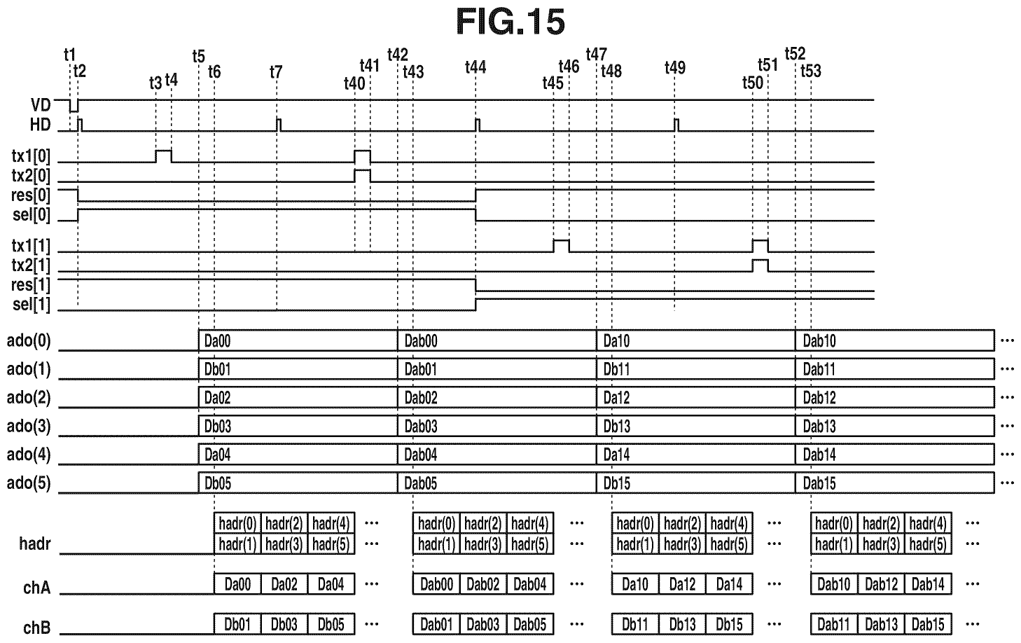

With reference to FIG. 15, a photoelectric conversion apparatus 1 (a signal processing method for a photoelectric conversion apparatus) according to a fourth exemplary embodiment of the disclosure is described. Components similar to those in the first, second, and third exemplary embodiments are designated by the same signs, and the description of these components is occasionally omitted or simplified.

The fourth exemplary embodiment is different from the first, second, and third exemplary embodiments in that signals output from a plurality of pixels 10 are not added (horizontally added, vertically added, or horizontally and vertically added) together. FIG. 15 is an example of a driving timing chart of the photoelectric conversion apparatus 1 according to the present exemplary embodiment.

In FIG. 15, the horizontal axis represents a time. FIG. 15 schematically illustrates the timings of driving pulses (control signals), digital values corresponding to digital signals, and digital values output to channels. The control signals illustrated in FIG. 15 correspond to the control signals illustrated in FIGS. 2A, 2B, and 4. An operation from a time t1 to a time t4 is similar to that described with reference to FIG. 5, and therefore is not described. The period from the time t1 to a time t7 and the period from the time t7 to a time t44 are occasionally referred to as a “first period” and a “second period”, respectively.

At the time t5, the AD conversion circuits 141 complete AD conversion and hold acquired digital values. A signal ado(0), a signal ado(2), and a signal ado(4) have a value Da00, a value Da02, and a value Da04, respectively, as digital values corresponding to the first photoelectric conversion elements 101 driven by the control signal tx1[0]. A signal ado(1), a signal ado(3), and a signal ado(5) have a value Db01, a value Db03, and a value Db05, respectively, as digital values corresponding to the second photoelectric conversion element 102 driven by the control signal tx1[0].

At the time t6, the timing signal output circuit 13 starts supplying a control signal hadr to the AD conversion unit 14, whereby the signals ado(0) to ado(5) are sequentially output. In the first cycle, a control signal hadr(0) and a control signal hadr(1) are input to switches 142. In the second cycle, a control signal hadr(2) and a control signal hadr(3) are input to switches 142. In the third cycle, a control signal hadr(4) and a control signal hadr(5) are input to switches 142. As a result, the values Da00, Da02, and Da04 are sequentially output to the horizontal transfer line 143 (the channel chA), and the values Db01, Db03, and Db05 are sequentially output to the horizontal transfer line 144 (the channel chB). Thus, a signal corresponding to the first photoelectric conversion element 101 disposed on the left side of each pixel 10 is output to the channel chA, and a signal corresponding to the second photoelectric conversion element 102 disposed on the right side of each pixel 10 is output to the channel chB.

At the time t7, the vertical scanning circuit 12 sets the control signal HD to the high level, whereby an operation for a single row starts. In the driving according to the first exemplary embodiment illustrated in FIG. 5, at the time t7, the operation transitions to control of the pixels 10 disposed in the next row. In the present exemplary embodiment, however, at the time t7, the operation does not transition to control of the pixels 10 disposed in the next row, and continues to control the pixels 10 disposed in the row controlled before the time t7 while maintaining the state at the time t7.

During the period from the time t40 to the time t41, the control signals tx1[0] changes to the high level and the control signal tx2[0] changes to a high level. Consequently, the first transfer transistor 103 and the second transfer transistor 104 are turned on, and charges output from the first photoelectric conversion element 101 and the second photoelectric conversion element 102 are added together by the FD 109. At the time t42, this addition signal is subjected to AD conversion by the AD conversion circuits 141, and the signals ado(0) to ado(5) output from the AD conversion circuits 141 have a value Dab00 to a value Dab05, respectively.

At the time t43, the timing signal output circuit 13 starts supplying the control signal hadr to the AD conversion unit 14, whereby the signals ado(0) to ado(5) are sequentially output. In the first cycle, the control signals hadr(0) and hadr(1) are input to switches 142. In the second cycle, the control signals hadr(2) and hadr(3) are input to switches 142. In the third cycle, the control signals hadr(4) and hadr(5) are input to switches 142. As a result, the values Dab00, Dab02, and Dab04 are sequentially output to the horizontal transfer line 143 (the channel chA), and the values Dab01, Dab03, and Dab05 are sequentially output to the horizontal transfer line 144 (the channel chB). Thus, a signal obtained by adding a signal corresponding to the first photoelectric conversion element 101 and a signal corresponding to the second photoelectric conversion element 102 is output to the channels chA and chB.

The signal correction circuit 2 temporarily holds the signals having the values Da00, Da02, and Da04 corresponding to the channel chA that are output during the period from the time t2 to the time t7. Then, the temporarily held signals are subtracted from the signals having the values Dab00, Dab02, and Dab04 corresponding to the channel chA that are output from the time t43. The signal correction circuit 2 temporarily holds the signals having the values Db01, Db03, and Db05 corresponding to the channel chB that are output during the period from the time t2 to the time t7. Then, the temporarily held signals are subtracted from the signals having the values Dab01, Dab03, and Dab05 corresponding to the channel chB that are output from the time t43. That is, the signal correction circuit 2 executes calculation processes such as (the value Dab00)−(the value Da00), (the value Dab02)−(the value Da02), and (the value Dab04)−(the value Da04) corresponding to the channel chA. The signal correction circuit 2 also executes calculation processes such as (the value Dab01)−(the value Db01), (the value Dab03)−(the value Db03), and (the value Dab05)−(the value Db05) corresponding to the channel chB.

Based on the above, a signal corresponding to the second photoelectric conversion element 102 can be obtained by (the value Dab00)−(the value Da00). A signal corresponding to the first photoelectric conversion element 101 can be obtained by (the value Dab01)−(the value Db01).

As described above, the process of reading signals twice from a plurality of pixels 10 disposed in any row by the control signal HD changing to the high level twice, and then subtracting the signal read at the first time from the signal read at the second time is performed on signals sequentially output from the channels chA and chB. By this driving, it is possible to obtain signals corresponding to the first photoelectric conversion elements 101 of a plurality of pixels 10 disposed in any row and signals corresponding to the second photoelectric conversion elements 102 of a plurality of pixels 10 disposed in any row. The focus detection circuit 20 of the signal correction circuit 2 detects the peak of each of the signals using the signals, whereby it is possible to perform phase difference detection.

The signals corresponding to the values Dab00 to Dab05 sequentially output from the channels chA and chB at and after the time t43 are used in image generation and appropriately corrected by the signal correction circuit 2.

At and after the time t44, the operation during the period from the time t2 to the time t44 is repeated. However, at and after the time t44, a row different from the row read during the period from the time t2 to the time t44 is read. That is, the control signal res[0] changes to a high level, the control signal sel[0] changes to a low level, the control signal res[1] changes to a low level, and the control signal sel[1] changes to a high level.

In the present exemplary embodiment, it is possible to perform image generation using signals output from a plurality of pixels 10 in a single frame and focus detection using the same signals. For example, in this configuration, a moving image is suitably captured while a distance is measured.

Further, the non-addition driving (the non-addition mode) illustrated in FIG. 15 according to the present exemplary embodiment and the addition driving (the addition mode) illustrated in FIG. 5 according to the first exemplary embodiment are combined together, whereby it is possible to optimally switch operation modes. For example, it is possible to switch between the use of the non-addition mode when a still image is captured and the use of the addition mode when a moving image is captured.

The period from the time t2 to the time t7 illustrated in FIG. 15 and the period from the time t2 to the time t7 illustrated in FIG. 5 can be regarded as the same period, and the positions of the pulses can also be the same. In this manner, when operation modes are changed, it is possible to change operation modes without changing the timing when the control signal HD changes to the high level, or changing the positions of pulses.

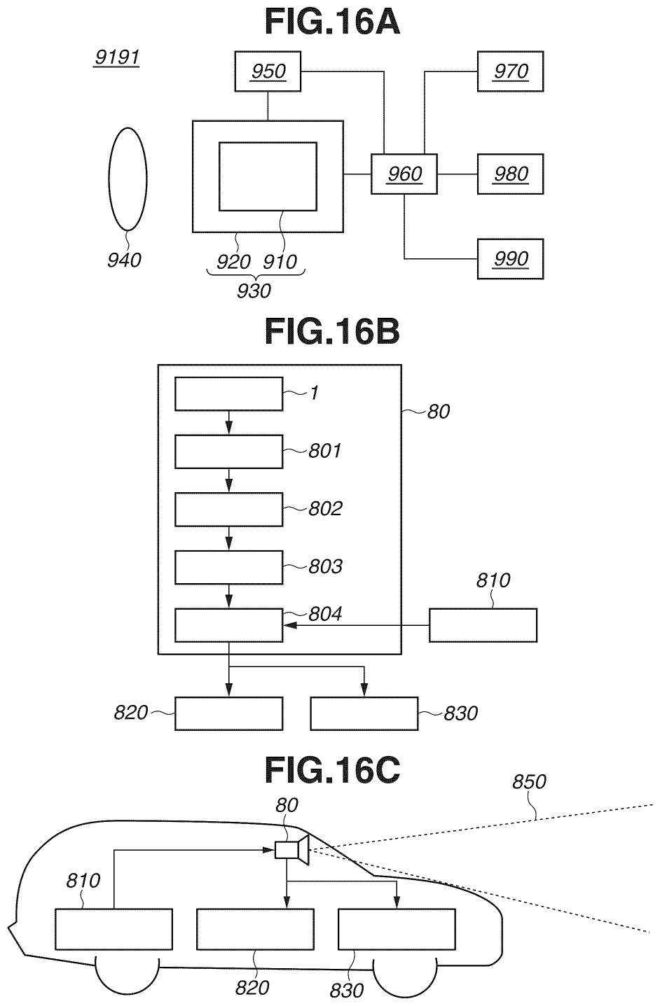

A fifth exemplary embodiment is applicable to any of the first to fourth exemplary embodiments. FIG. 16A is a schematic diagram illustrating a device 9191 including a semiconductor apparatus 930 according to the present exemplary embodiment. As the semiconductor apparatus 930, the photoelectric conversion apparatus 1 according to each of the above exemplary embodiments can be used. The device 9191 including the semiconductor apparatus 930 is described in detail. The semiconductor apparatus 930 can include a semiconductor device 910. The semiconductor apparatus 930 can include a package 920 for accommodating the semiconductor device 910 in addition to the semiconductor device 910. The package 920 can include a base to which the semiconductor device 910 is fixed, and a cover body, such as glass, opposed to the semiconductor device 910. The package 920 can further include a joint member, such as a bonding wire or a bump, connecting a terminal provided in the base and a terminal provided in the semiconductor device 910.

The device 9191 can include at least any of an optical apparatus 940, a control apparatus 950, a processing apparatus 960, a display apparatus 970, a storage apparatus 980, and a machine apparatus 990. The optical apparatus 940 is compatible with the semiconductor apparatus 930. For example, the optical system 940 is a lens, a shutter, and a mirror and includes an optical system that guides light to the semiconductor apparatus 930. The control apparatus 950 controls the semiconductor apparatus 930. The control apparatus 950 is a semiconductor apparatus such as an application-specific integrated circuit (ASIC).

The processing apparatus 960 processes a signal output from the semiconductor apparatus 930. The processing apparatus 960 is a semiconductor apparatus such as a central processing unit (CPU) or an ASIC for configuring an analog front end (AFE) or a digital front end (DFE). The display apparatus 970 is an electroluminescent (EL) display apparatus or a liquid crystal display apparatus that displays information (an image) obtained by the semiconductor apparatus 930. The storage apparatus 980 is a magnetic device or a semiconductor device that stores information (an image) obtained by the semiconductor apparatus 930. The storage apparatus 980 is a volatile memory such as a static random-access memory (SRAM) or a dynamic random-access memory (DRAM), or a non-volatile memory such as a flash memory or a hard disk drive.

The machine apparatus 990 includes a movable portion or a propulsive portion such as a motor or an engine. The device 9191 displays a signal output from the semiconductor apparatus 930 on the display apparatus 970, or transmits a signal output from the semiconductor apparatus 930 to outside, using a communication apparatus (not illustrated) included in the device 9191. To this end, in one embodiment, it is desirable that the device 9191 further includes the storage apparatus 980 and the processing apparatus 960 separately from a storage circuit and an arithmetic circuit included in the semiconductor apparatus 930. The machine apparatus 990 may be controlled based on a signal output from the semiconductor apparatus 930.

The device 9191 is suitable for an electronic device such as an information terminal having an imaging function (e.g., a smartphone or a wearable terminal) or a camera (e.g., an interchangeable lens camera, a compact camera, a video camera, or a monitoring camera). The machine apparatus 990 in the camera can drive the components of the optical apparatus 940 for a zooming operation, a focusing operation, and a shutter operation. Alternatively, the machine apparatus 990 in the camera can move the semiconductor apparatus 930 for an image stabilization operation.

The device 9191 can also be a transportation device such as a vehicle, a vessel, or an aircraft. The machine apparatus 990 in the transportation device can be used as a moving device. The device 9191 as the transportation device is suitable for a transportation device that transports the semiconductor apparatus 930, or a transportation device that assists and/or automates driving (maneuvering) by an imaging function. The processing apparatus 960 for assisting and/or automating driving (maneuvering) can perform processing for operating the machine apparatus 990 as the moving device based on information obtained by the semiconductor apparatus 930. Alternatively, the device 9191 may be a medical device such as an endoscope, a measurement device such as a distance measurement sensor, an analysis device such as an electron microscope, an office device such as a copying machine, or an industrial device such as a robot.

According to the above exemplary embodiments, it is possible to obtain excellent pixel characteristics. Thus, it is possible to increase the value of a semiconductor apparatus. The increase in the value corresponds to at least any of the addition of a function, an improvement in the performance, improvements in the characteristics, an improvement in the reliability, an improvement in the manufacturing yield, a reduction in the environmental load, a reduction in the cost, a reduction in the size, and a reduction in the weight.

Thus, if the semiconductor apparatus 930 according to the present exemplary embodiment is used for the device 9191, it is also possible to improve the value of the device 9191. For example, when the semiconductor apparatus 930 is mounted on a transportation device, and an image outside the transportation device is captured, or the external environment is measured, it is possible to obtain excellent performance. Thus, in a case where a transportation device is manufactured and sold, the determination of the mounting of the semiconductor apparatus 930 according to the present exemplary embodiment on the transportation device is advantageous in enhancing the performance of the transportation device itself. Particularly, the semiconductor apparatus 930 is suitable for a transportation device that performs driving assistance and/or automatic driving of the transportation device using information obtained by a semiconductor apparatus.

With reference to FIGS. 16B and 16C, a photoelectric conversion system and a moving body according to the present exemplary embodiment are described.

FIG. 16B illustrates an example of a photoelectric conversion system regarding an in-vehicle camera. A photoelectric conversion system 80 includes a photoelectric conversion apparatus 1. The photoelectric conversion apparatus 1 is the photoelectric conversion apparatus 1 (an imaging apparatus) according to any of the above exemplary embodiments. The photoelectric conversion system 80 includes an image processing unit 801 that performs image processing on a plurality of pieces of image data acquired by the photoelectric conversion apparatus 1, and a parallax acquisition unit 802 that calculates a parallax (the phase difference between parallax images) from the plurality of pieces of image data acquired by the photoelectric conversion system 80. The photoelectric conversion system 80 may include an optical system (not illustrated) that guides light to the photoelectric conversion apparatus 1, such as a lens, a shutter, and a mirror.

A plurality of photoelectric conversion elements may receive beams passing through positions different from each other in the pupil of the optical system, whereby the photoelectric conversion apparatus 1 may output pieces of image data corresponding to the beams passing through the different positions. Then, the parallax acquisition unit 802 may calculate a parallax using the output pieces of image data. The photoelectric conversion system 80 also includes a distance acquisition unit 803 that calculates the distance to a target object based on the calculated parallax, and a collision determination unit 804 that, based on the calculated distance, determines whether there is a possibility of a collision. The parallax acquisition unit 802 and the distance acquisition unit 803 are examples of a distance information acquisition unit that acquires distance information regarding the distance to a target object. That is, the distance information is information regarding the parallax, the amount of defocus, and the distance to the target object. Using any of these pieces of distance information, the collision determination unit 804 may determine the possibility of a collision. The distance information may be acquired using time of flight (ToF). The distance information acquisition unit may be achieved by exclusively designed hardware, or may be achieved by a software module. Alternatively, the distance information acquisition unit may be achieved by a field-programmable gate array (FPGA) or an ASIC, or may be achieved by the combination of these.

The photoelectric conversion system 80 is connected to a vehicle information acquisition apparatus 810 and can acquire vehicle information such as the speed of a vehicle, the yaw rate, and the steering angle. The photoelectric conversion system 80 is also connected to a control electronic control unit (ECU) 820 that is a control apparatus that outputs a control signal for producing a braking force in the vehicle based on the determination result of the collision determination unit 804. The photoelectric conversion system 80 is also connected to an alarm apparatus 830 that gives an alarm to a driver based on the determination result of the collision determination unit 804. For example, if there is a high possibility of a collision as the determination result of the collision determination unit 804, the control ECU 820 applies a brake, returns the gas pedal, or suppresses the engine output, thereby controlling the vehicle to avoid a collision and reduce damage. The alarm apparatus 830 warns a user by setting off an alarm such as a sound, displaying alarm information on a screen of an automotive navigation system, or imparting a vibration to a seat belt or the steering.

In the present exemplary embodiment, the photoelectric conversion system 80 captures the periphery, such as the front direction or the rear direction, of the vehicle. FIG. 16C illustrates the photoelectric conversion system 80 in a case where the photoelectric conversion system 80 captures the front direction of the vehicle (an imaging range 850). The vehicle information acquisition apparatus 810 sends an instruction to the photoelectric conversion system 80 or the photoelectric conversion apparatus 1. With this configuration, it is possible to further improve the accuracy of distance measurement.

In the above description, an example has been described where a vehicle is controlled to avoid colliding with another vehicle. Alternatively, the present exemplary embodiment is also applicable to control for automatically driving a vehicle by following another vehicle, or control for automatically driving a vehicle so as to stay in a lane. Further, the photoelectric conversion system 80 can be applied not only to a vehicle such as an automobile but also to a moving body (a moving apparatus) such as a vessel, an aircraft, or an industrial robot. The moving body includes one or both of a driving force generation unit that generates a driving force mainly used to move the moving body, and a rotating body mainly used to move the moving body. The driving force generation unit can be an engine or a motor. The rotating body can be a tire, a wheel, a screw of a vessel, or a propeller of an aircraft. Additionally, the photoelectric conversion system 80 can be applied not only to a moving body but also to a device widely using object recognition, such as an intelligent transportation system (ITS).

In the specification, the expressions “A or B”, “at least one of A and B”, “at least one of A and/or B”, and “one or more of A and/or B” include all the possible combinations of the listed items, unless explicitly defined. That is, it is understood that the above expressions disclose all of a case where at least one A is included, a case where at least one B is included, and a case where both of at least one A and at least one B are included. This is also similarly applied to the combination of three or more elements.

The above exemplary embodiments can be appropriately changed without departing from their technical ideas. The disclosed content of the specification includes not only the items described in the specification but also all the items that can be understood from the specification and the drawings attached to the specification. The disclosed content of the specification includes a complement of the concepts described in the specification. That is, for example, if the specification states that “A is larger than B”, and even if the specification omits the statement that “A is not larger than B”, the specification can be said to state that “A is not larger than B”. This is because the statement that “A is larger than B” is based on the premise of the consideration that “A is not larger than B”.

According to the aspect of the embodiments, it is possible to perform focus detection and image generation at high speed.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-125745. filed August 1. 2024, which is hereby incorporated by reference herein in its entirety.

What is claimed is:

1. A conversion apparatus including a plurality of pixels disposed in a matrix, the conversion apparatus comprising:
a first pixel and a second pixel disposed in a first row;
a first microlens corresponding to the first pixel; and
a second microlens corresponding to the second pixel,
wherein the first pixel includes a first conversion element configured to convert light passing through the first microlens, thereby generating a first charge, a second conversion element configured to convert light passing through the first microlens, thereby generating a second charge, a first floating diffusion configured to accumulate at least one of the first and second charges, a first transfer transistor configured to transfer the first charge to the first floating diffusion, and a second transfer transistor configured to transfer the second charge to the first floating diffusion, and
wherein the second pixel includes a third conversion element configured to convert light passing through the second microlens, thereby generating a third charge, a fourth conversion element configured to convert light passing through the second microlens, thereby generating a fourth charge, a second floating diffusion configured to accumulate at least one of the third and fourth charges, a third transfer transistor configured to transfer the third charge to the second floating diffusion, and a fourth transfer transistor configured to transfer the fourth charge to the second floating diffusion,
the conversion apparatus comprising a first control line connected to the first and fourth transfer transistors and a second control line connected to the second and third transfer transistors,
wherein the third and fourth conversion elements are disposed in order in a direction from the first conversion element to the second conversion element, and
wherein using the first control line, a set of a signal based on the first charge and a signal based on the fourth charge is output for use in focus detection and image generation.

2. The conversion apparatus according to claim 1, wherein using the second control line, a set of a signal based on the second charge and a signal based on the third charge is output for use in focus detection and image generation.

3. The conversion apparatus according to claim 1, wherein using the first and second control lines, a set of a signal based on the first charge and a signal based on the second charge is output for use in focus detection and image generation.

4. The conversion apparatus according to claim 1, further comprising:
a third pixel and a fourth pixel disposed in a second row;
a third microlens corresponding to the third pixel; and
a fourth microlens corresponding to the fourth pixel,
wherein the first and third pixels are disposed in the same column, and the second and fourth pixels are disposed in the same column,
wherein the third pixel includes a fifth conversion element configured to convert light passing through the third microlens, thereby generating a fifth charge, a sixth conversion element configured to convert light passing through the third microlens, thereby generating a sixth charge, a third floating diffusion configured to accumulate at least one of the fifth and sixth charges, a fifth transfer transistor configured to transfer the fifth charge to the third floating diffusion, and a sixth transfer transistor configured to transfer the sixth charge to the third floating diffusion,
wherein the fourth pixel includes a seventh conversion element configured to convert light passing through the fourth microlens, thereby generating a seventh charge, an eighth conversion element configured to convert light passing through the fourth microlens, thereby generating an eighth charge, a fourth floating diffusion configured to accumulate at least one of the seventh and eighth charges, a seventh transfer transistor configured to transfer the seventh charge to the fourth floating diffusion, and an eighth transfer transistor configured to transfer the eighth charge to the fourth floating diffusion,
the conversion apparatus further comprising a third control line connected to the fifth and eighth transfer transistors, and a fourth control line connected to the sixth and seventh transfer transistors,
wherein the fifth and sixth conversion elements are disposed in order in the direction from the first conversion element to the second conversion element,
wherein the seventh and eighth conversion elements are disposed in order in the direction from the first conversion element to the second conversion element, and
wherein using the third control line, a set of a signal based on the fifth charge and a signal based on the eighth charge is output for use in focus detection and image generation.

5. The conversion apparatus according to claim 4, wherein after the first control line is used, the second control line is not used, and the third control line is used.

6. The conversion apparatus according to claim 1, further comprising color filters,
wherein one of the color filters corresponding to the first pixel and one of the color filters corresponding to the second pixels are of the same color.

7. The conversion apparatus according to claim 1, further comprising:
a fifth pixel disposed in the first row; and
a fifth microlens corresponding to the fifth pixel,
wherein the fifth pixel is disposed between the first and second pixels,
wherein the fifth pixel includes a ninth conversion element configured to convert light passing through the fifth microlens, thereby generating a ninth charge, a tenth conversion element configured to convert light passing through the fifth microlens, thereby generating a tenth charge, a fifth floating diffusion configured to accumulate at least one of the ninth and tenth charges, a ninth transfer transistor configured to transfer the ninth charge to the fifth floating diffusion, and a tenth transfer transistor configured to transfer the tenth charge to the fifth floating diffusion,
wherein the ninth and tenth conversion elements are disposed in order in the direction from the first conversion element to the second conversion element, and
wherein the first control line is connected to the ninth transfer transistor, and the second control line is connected to the tenth transfer transistor.

8. The conversion apparatus according to claim 7, further comprising color filters,
wherein one of the color filters corresponding to the first pixel and one of the color filters corresponding to the second pixel are of the same color, and the color filter corresponding to the first pixel and one of the color filters corresponding to the fifth pixel are of different colors.

9. The conversion apparatus according to claim 1, further comprising a compression circuit,
wherein the compression circuit performs at least one of a thinning process, an addition process, and a number-of-bits reduction process on a signal to be output for use in focus detection.

10. The conversion apparatus according to claim 1, wherein the set of the signal based on the first charge and the signal based on the fourth charge is output in a single frame for use in focus detection and image generation.

11. The conversion apparatus according to claim 1, wherein the first floating diffusion is shared by the first and second conversion elements.

12. The conversion apparatus according to claim 1, wherein the first control line is used during a first period, and the first and second control lines are used during a second period.

13. The conversion apparatus according to claim 12, wherein focus detection is performed by subtracting a signal output during the first period from a signal output during the second period.

14. The conversion apparatus according to claim 1, further comprising a focus detection circuit,
wherein the focus detection circuit performs focus detection using the set of the signal based on the first charge and the signal based on the fourth charge.

15. The conversion apparatus according to claim 1, further comprising an image generation circuit,
wherein the image generation circuit performs image generation using the set of the signal based on the first charge and the signal based on the fourth charge.

16. The conversion apparatus according to claim 15, wherein the image generation circuit includes an addition circuit configured to perform an addition process on signals output from the plurality of pixels, and according to a plurality of operation modes included in the conversion apparatus, the addition circuit changes the number of signals on which the addition process is performed.

17. A conversion system comprising:
the conversion apparatus according to claim 1; and
a focus detection circuit,
wherein the focus detection circuit performs focus detection using the set of the signal based on the first charge and the signal based on the fourth charge.

18. A conversion system comprising:
the conversion apparatus according to claim 1; and
an image generation circuit,
wherein the image generation circuit performs image generation using the set of the signal based on the first charge and the signal based on the fourth charge.

19. A device comprising:
the conversion apparatus according to claim 1; and
at least any of:
an optical apparatus configured to guide light to the conversion apparatus;
a control apparatus configured to control the conversion apparatus;
a processing apparatus configured to process a signal output from the conversion apparatus;
a display apparatus configured to display information obtained by the conversion apparatus;
a storage apparatus configured to store information obtained by the conversion apparatus; and
a machine apparatus configured to operate based on information obtained by the conversion apparatus.

20. A signal processing method for a conversion apparatus comprising:
a plurality of pixels disposed in a matrix;
a first pixel and a second pixel disposed in a first row;
a first microlens corresponding to the first pixel; and
a second microlens corresponding to the second pixel,
wherein the first pixel includes a first conversion element configured to convert light passing through the first microlens, thereby generating a first charge, a second conversion element configured to convert light passing through the first microlens, thereby generating a second charge, a first floating diffusion configured to accumulate at least one of the first and second charges, a first transfer transistor configured to transfer the first charge to the first floating diffusion, and a second transfer transistor configured to transfer the second charge to the first floating diffusion, and
wherein the second pixel includes a third conversion element configured to convert light passing through the second microlens, thereby generating a third charge, a fourth conversion element configured to convert light passing through the second microlens, thereby generating a fourth charge, a second floating diffusion configured to accumulate at least one of the third and fourth charges, a third transfer transistor configured to transfer the third charge to the second floating diffusion, and a fourth transfer transistor configured to transfer the fourth charge to the second floating diffusion,
the conversion apparatus comprising a first control line connected to the first and fourth transfer transistors and a second control line connected to the second and third transfer transistors,
wherein the third and fourth conversion elements are disposed in order in a direction from the first conversion element to the second conversion element, and
wherein using the first control line, a set of a signal based on the first charge and a signal based on the fourth charge is output for use in focus detection and image generation,
the signal processing method comprising:
performing focus detection and image generation using the set of the signal based on the first charge and the signal based on the fourth charge output from the conversion apparatus.
